(19) United States
(12) Patent Application Publication
(10) Pub. No.: US 2025/0046717 A1
(43) Pub. Date: Feb. 6, 2025

(54) Microelectronic Devices with Good Reliability and Related Compositions and Methods

(71) Applicant: Fujifilm Electronic Materials U.S.A, Inc., N. Kingstown, RI (US)

(72) Inventors: Stefan Vanclooster, East Flandres (BE); Satoshi Matsui, Zwijndrecht (BE); Sanjay Malik, Attleboro, MA (US); Binod B. De, Attleboro, MA (US); William A. Reinerth, Riverside, RI (US); Stephanie Dilocker, Attleboro, MA (US); Juliet Kotyk, Barrington, RI (US)

(21) Appl. No.: 18/782,630

(22) Filed: Jul. 24, 2024

Related U.S. Application Data
(60) Provisional application No. 63/529,819, filed on Jul. 31, 2023.

(51) Int. Cl. H01L 23/532; C08L 33/24

(52) U.S. Cl. CPC H01L 23/5329; C08L 33/24

(57) ABSTRACT

The present disclosure generally relates to microelectronic devices with good reliability and related compositions and methods. In some embodiments, the methods include providing a composition comprising a hydrophobic multifunctional (meth)acrylate crosslinker and a polymer, and reacting the composition to provide a dielectric layer, wherein, when the dielectric layer is present in a microelectronic device, the microelectronic device exhibits good reliability. In certain embodiments, the compositions include a fully imidized polyimide and a hydrophobic multifunctional (meth)acrylate crosslinker, wherein the dielectric composition is suitable to provide a dielectric layer that imparts good reliability to a microelectronic device when the dielectric layer is present in the device.

### CROSS-REFERENCE TO RELATED APPLICATION

The present application claims priority to U.S. Provisional Application Ser. No. 63/529,819, filed on Jul. 31, 2023, the contents of which are hereby incorporated by reference in their entirety.

### FIELD OF THE DISCLOSURE

The present disclosure generally relates to microelectronic devices with good reliability and related compositions and methods. In some embodiments, the methods include providing a composition comprising a hydrophobic multifunctional (meth)acrylate crosslinker and a polymer, and reacting the composition to provide a dielectric layer, wherein, when the dielectric layer is present in a microelectronic device, the microelectronic device exhibits good reliability. In certain embodiments, the compositions include a fully imidized polyimide and a hydrophobic multifunctional (meth)acrylate crosslinker, wherein the dielectric composition is suitable to provide a dielectric layer that imparts good reliability to a microelectronic device when the dielectric layer is present in the microelectronic device. Optionally, the polymer includes at least one polybenzoxazole precursor polymer, at least one polyimide precursor polymer, or at least one fully imidized polyimide polymer, or mixtures thereof, and at least one hydrophobic multifunctional (meth)acrylate crosslinker.

### BACKGROUND OF THE DISCLOSURE

In general, various desirable properties of dielectric materials for semiconductor packaging applications are continuously evolving. Generally, the trend in electronic packaging continues to move towards faster processing speeds, increased complexity and higher packing density while maintaining a high level of reliability.

In many cases, reliability is a parameter that is considered when developing advanced integrated circuit (IC) packaging technologies. Typically, component level reliability (CLR) and board level reliability (BLR) are two reliability steps in IC packaging technologies. If a semiconductor chip can pass reliability tests for these two levels, it can often be used in a desired application. For advanced/emerging package technologies, BLR testing may be conducted to determine the solder joint interconnect reliability using daisy-chained test vehicles. Failure analysis is conducted on failed samples to determine the cause. Preconditioning, temperature humidity bias (THB), highly accelerated stress test (HAST), biased humidity stress test (bHAST), unbiased HAST (uHAST), high temperature storage (HTS) are commonly used stress tests applied to semiconductor packaging materials to determine board level reliability (BLR). BLR is the proportion of devices used from time zero that will not have failed by a given time ‘t’. bHAST is a test of electrical insulation reliability under highly accelerated temperature, humidity, and bias voltage.

### SUMMARY OF THE DISCLOSURE

In some embodiments, the disclosure provides methods that include providing a composition comprising a hydrophobic multifunctional (meth)acrylate crosslinker and a polymer, and reacting the composition to provide a dielectric layer, wherein, when the dielectric layer is present in a microelectronic device, the microelectronic device exhibits good reliability. In certain embodiments, the disclosure provides compositions that include a fully imidized polyimide and a hydrophobic multifunctional (meth)acrylate crosslinker, wherein the dielectric composition is suitable to provide a dielectric layer that imparts good reliability to a microelectronic device when the dielectric layer is present in the microelectronic device. The polymer can include one or more polybenzoxazole precursor polymers, polyimide precursor polymers, and/or fully imidized polyimide polymers. The dielectric layer can be cast from such a composition. Compositions of the disclosure can form relatively uniform films which can be developed after exposure to relatively long UV wavelength (e.g., about 365 nm) to form a patterned dielectric film, wherein the patterned dielectric film can exhibit desirable properties according to one or more reliability tests.

In an aspect, the disclosure provides a method, comprising: providing a composition comprising a hydrophobic multifunctional (meth)acrylate crosslinker and a polymer; and processing the composition to provide a dielectric layer, wherein, when the dielectric layer is present in a microelectronic device, the microelectronic device exhibits good reliability.

In some embodiments, the hydrophobic multifunctional (meth)acrylate crosslinker has a log P value of at least 0.5.

In some embodiments, the hydrophobic multifunctional (meth)acrylate crosslinker comprises at least one member selected from difunctional, trifunctional, tetrafunctional, and hexafunctional (meth)acrylates, and wherein each of the hydrophobic multifunctional (meth)acrylate crosslinkers has a log P value from about 0.5 to about 8.0.

In some embodiments, the composition further comprises a corrosion inhibitor. In certain embodiments, the corrosion inhibitor has a log P value from about-1.0 to about 6.0.

In some embodiments, the composition further comprises a photoinitiator. In certain embodiments the photoinitiator comprises at least one member selected from oxime ester, titanocene, acyl germanium compound, and peroxide.

In some embodiments, the composition further comprises an organic solvent. In certain embodiments, the organic solvent comprises at least one member selected from alkylene carbonates, lactones, cycloketones, linear ketones, alkyl esters, alkyl ester alcohol, alkyl ether alcohols, alkyl ether ester, glycol ester, glycol ether, cyclic ether, pyrrolidone, and dialkylsulfoxide.

In some embodiments, the polymer comprises at least one member selected from a polybenzoxazole precursor polymer, a polyimide precursor polymer, or a fully imidized polyimide polymer. In certain embodiments, the polymer comprises a fully imidized polyimide polymer. In certain embodiments, the fully imidized polyimide polymer comprises a functional group. In certain embodiments, the fully imidized polyimide polymer comprises an alkaline soluble polymer. In certain embodiments, the fully imidized polyimide polymer comprises a fluorine-atom free polymer.

In some embodiments, the polymer is present in an amount of from about 0.1% to about 55% by weight based on a solid weight of the composition.

In some embodiments, the hydrophobic multifunctional (meth)acrylate crosslinker is present in an amount of from about 0.5% to about 25% by weight based on a solid weight of the composition.

In some embodiments, the composition further comprises at least one member selected from the group consisting of an adhesion promoter, a surfactant, a filler, a pigment, a dye, and a metal-containing (meth)acrylate compound.

In some embodiments, the composition further comprises at least one photosensitizer selected from the group consisting of benzophenones, thioxanthones, anthraquinones, anthracenes, and coumarines.

In some embodiments, the composition is substantially free of fluorine.

In some embodiments, when the dielectric layer is present in the microelectronic device, and the microelectronic device passes at least one test selected from the group consisting of HAST, bHAST, HTS and TCT.

In some embodiments, the method further comprises: depositing the composition on a substrate to form a film; exposing the film to radiation or heat or a combination of radiation and heat to crosslink the hydrophobic multifunctional (meth)acrylate crosslinker to provide the dielectric layer; and patterning the dielectric layer to form a patterned dielectric layer having openings. In some embodiments, the disclosure provides a patterned dielectric layer produced by such embodiments.

In some embodiments, the method further comprises: incorporating the dielectric layer into the microelectronic device.

In some embodiments, the substrate comprises at least one member selected from organic film, an epoxy molded compound (EMC), silicon, glass, copper, stainless steel, a copper cladded laminate (CCL), aluminum, silicon oxide, and silicon nitride.

In some embodiments, the method further comprises: optionally depositing a seed layer on the patterned dielectric film; and depositing a metal layer in an opening in the patterned dielectric film to form a metal pattern.

In some embodiments, the semiconductor device is an integrated circuit, a light emitting diode, a solar cell, or a transistor.

In some embodiments, the method further comprises supporting the dielectric film with a carrier layer.

In some embodiments, the further comprises: coating a carrier substrate with the composition to form a coated composition; drying the coated composition to form the dielectric layer; and optionally applying a protective layer to the dielectric layer to form the dry film structure.

In some embodiments, the method further comprises applying the dry film structure onto an electronic substrate to form a laminate, wherein the dielectric layer in the laminate is disposed between the electronic substrate and the carrier substrate.

In some embodiments, the method further comprises depositing the dielectric film onto a substrate having a copper pattern to form a dielectric film, wherein the difference in height between the highest and lowest points on a surface of the dielectric film is at most about 2 microns.

In an aspect, the disclosure provides a composition, comprising: a fully imidized polyimide; and a hydrophobic multifunctional (meth)acrylate crosslinker, wherein the dielectric composition is suitable to provide a dielectric layer that imparts good reliability to a microelectronic device when the dielectric layer is present in the microelectronic device.

In some embodiments, the hydrophobic multifunctional (meth)acrylate crosslinker has a log P value of at least 0.5.

In some embodiments, the hydrophobic multifunctional (meth)acrylate crosslinker comprises at least one member selected from difunctional, trifunctional, tetrafunctional, and hexafunctional (meth)acrylates, and wherein each of the hydrophobic multifunctional (meth)acrylate crosslinkers has a log P value from about 0.5 to about 8.0.

In some embodiments, the composition further comprises a corrosion inhibitor. In certain embodiments, the corrosion inhibitor has a log P value from about-1.0 to about 6.0.

In some embodiments, the composition further comprises a photoinitiator. In certain embodiments the photoinitiator comprises at least one member selected from oxime ester, titanocene, acyl germanium compound, and peroxide.

In some embodiments, the composition further comprises an organic solvent. In certain embodiments, the organic solvent comprises at least one member selected from alkylene carbonates, lactones, cycloketones, linear ketones, alkyl esters, alkyl ester alcohol, alkyl ether alcohols, alkyl ether ester, glycol ester, glycol ether, cyclic ether, pyrrolidone, and dialkylsulfoxide.

In some embodiments, the polymer comprises at least one member selected from a polybenzoxazole precursor polymer, a polyimide precursor polymer, or a fully imidized polyimide polymer. In certain embodiments, the polymer comprises a fully imidized polyimide polymer. In certain embodiments, the fully imidized polyimide polymer comprises a functional group. In certain embodiments, the fully imidized polyimide polymer comprises an alkaline soluble polymer. In certain embodiments, the fully imidized polyimide polymer comprises a fluorine-atom free polymer.

In some embodiments, the polymer is present in an amount of from about 0.1% to about 55% by weight based on a solid weight of the composition.

In some embodiments, the hydrophobic multifunctional (meth)acrylate crosslinker is present in an amount of from about 0.5% to about 25% by weight based on a solid weight of the composition.

In some embodiments, the composition further comprises at least one member selected from the group consisting of an adhesion promoter, a surfactant, a filler, a pigment, a dye, and a metal-containing (meth)acrylate compound.

In some embodiments, the composition further comprises at least one photosensitizer selected from the group consisting of benzophenones, thioxanthones, anthraquinones, anthracenes, and coumarines.

In some embodiments, the composition is substantially free of fluorine.

In some embodiments, when the dielectric layer is present in the microelectronic device, and the microelectronic device passes at least one test selected from the group consisting of HAST, bHAST, HTS and TCT.

### DESCRIPTION OF THE DRAWINGS

FIG. 1 is a plot of an example of Resistance [Ohm] vs Time (h) of a successful bHAST Plot of formulation FE-33.

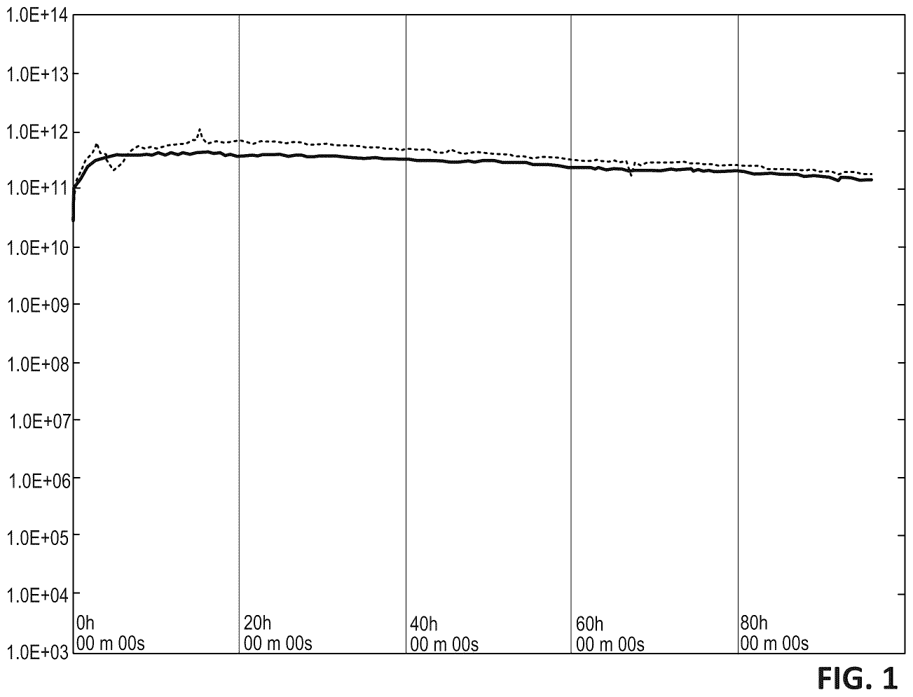

FIG. 2 is a plot of an example of Resistance [Ohm] vs Time (h) of an unsuccessful bHAST Plot of formulation FE-9.

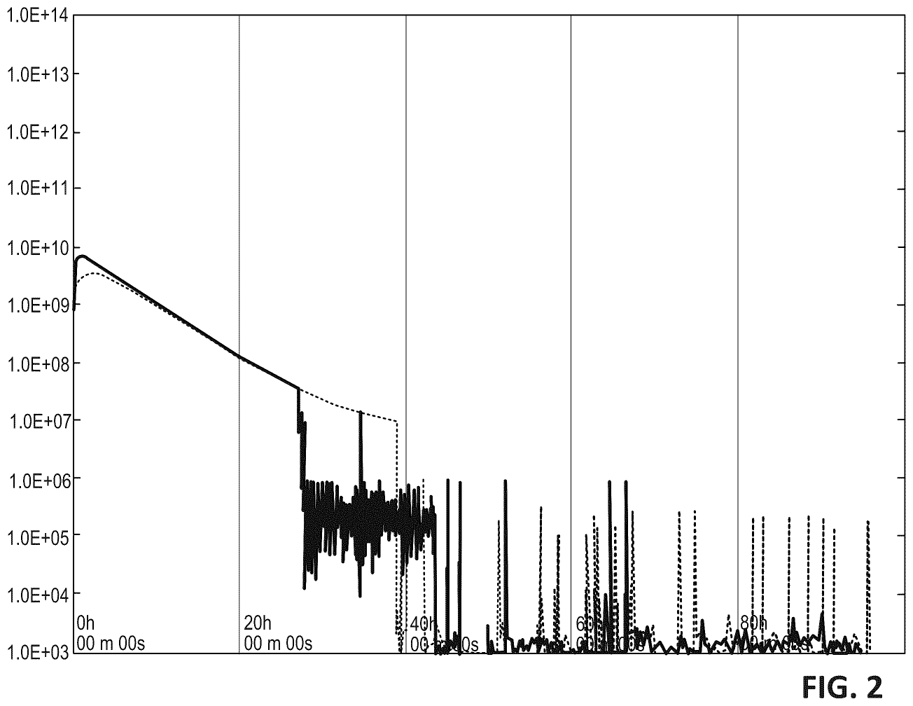

### DETAILED DESCRIPTION OF THE DISCLOSURE

The present disclosure relates to methods and compositions that may be used to provide microelectronic devices having good reliability. In some embodiments, the compositions described herein can be photosensitive. For example, the compositions described herein can be sensitive to electromagnetic or actinic radiation in the wavelength range of from about 150 nm to 600 nm (e.g., 405 nm), thereby resulting in solubility changes (e.g., solubility increase or decrease) in a suitable developer (e.g., cyclopentanone).

In some embodiments, the dielectric film forming compositions employed by the methods set forth herein include at least one fully imidized polyimide. The fully imidized polyimide can be a polymer of structure (I):

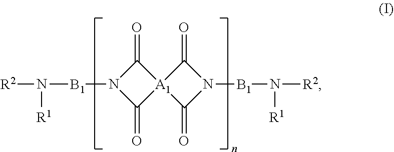

wherein R¹ is a hydrogen or a C₁-C₁₂ alkyl, C₂-C₁₂ alkenyl, C₄-C₁₈ cycloalkyl, C₆-C₂₂ aryl, or C₆-C₂₂ heteroaryl group; R² is an end group (e.g., a functional or non-functional end group), n is an integer greater than 5 (e.g., 5-200), B₁ is the nucleus of a precursor diamine and A₁ is the nucleus of a precursor dianhydride. As used herein, when referring to the precursor diamine, “nucleus” refers to the moiety between two amine functional groups. When referring to the precursor dianhydride, “nucleus” refers to the moiety between two anhydride functional groups. Examples of such diamines and dianhydrides are disclosed in, e.g., U.S. Pat. No. 9,695,284, the entire contents of which are hereby incorporated by reference. Functional or non-functional acid anhydrides or acid chlorides can be used for end-capping of unreacted amine functionality on the amino-terminated polyamic acid.

Examples of suitable diamines that can be used to prepare the polymer of structure (I) include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl) propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl) benzidine, 3,3′-bis(trifluoromethyl) benzidine, 2,2-bis[4-(4-aminophenoxyphenyl)]hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline) isopropylidene, bis(p-beta-amino-t-butylphenyl) ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy)phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene,4,4′-diamino-2,2′-bis(trifluoromethyl) biphenyl, H-fluorene-2,6-diamine, bis(aminopropyl)tetramethyldisiloxane (BATMS), bis(aminopropyl)tetraphenyldisiloxane, bis(4-aminophenoxy)dimethylsilane and the like. Any of these diamines can be used individually or in combination in any suitable ratio to form a polyimide described herein.

Examples of suitable dianhydrides that can be used to prepare the polymer of structure (I) include, but are not limited to, 1-(3′,4′-dicarboxyphenyl)-1,3,3-trimethylindan-5,6-dicarboxylic acid dianhydride, 1-(3′,4′-dicarboxyphenyl)-1,3,3-trimethylindan-6,7-dicarboxylic acid dianhydride, 1-(3′,4′-dicarboxyphenyl)-3-methylindan-5,6-dicarboxylic acid dianhydride, 1-(3′,4′-dicarboxyphenyl)-3-methylindan-6,7-dicarboxylic acid anhydride, pyromellitic dianhydride, benzene-1,2,3,4-tetracarboxylic dianhydride, 2,3,5,6-naphthalenetetracarboxylic acid dianhydride, 2,3,6,7-naphthalenetetracarboxylic acid dianhydride, 1,4,5,8-naphthalenetetracarboxylic acid dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-,8,9,10-tetracarboxylic dianhydride, 3,4,9,10-perylenetetracarboxylic acid dianhydride, pyrazine-2,3,5,6-tetracarboxylic dianhydride, thiophene-2,3,4,5-tetracarboxylic dianhydride, 2,3,5,6-pyridinetetracarboxylic acid dianhydride, butane-1,2,3,4-tetracarboxylic acid dianhydride, 1,2,3,4-cyclopentanetetracarboxylic acid dianhydride, cyclobutane-1,2,3,4-tetracarboxylic acid dianhydride, cyclopentane-1,2,3,4-tetracarboxylic acid dianhydride, cyclohexane-1,2,4,5-tetracarboxylic acid dianhydride, norbornane-2,3,5,6-tetracarboxylic acid dianhydride, bicyclo[2.2.2]oct-7-ene-3,4,8,9-tetracarboxylic acid dianhydride, tetracyclo[4.4.1.0^{2,5}.0^{7,10}]undecane-1,2,3,4-tetracarboxylic acid dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, 3,3′,4,4′-diphenylsulfone tetracarboxylic dianhydride, 2,2′,3,3′-diphenylsulfone tetracarboxylic dianhydride, 2,3,3′,4′-diphenylsulfone tetracarboxylic dianhydride, 3,3′,4,4′-diphenylether tetracarboxylic dianhydride, 2,2′,3,3′-diphenylether tetracarboxylic dianhydride, 2,3,3′,4′-diphenylether tetracarboxylic dianhydride, 2,2-[bis(3,4-dicarboxyphenyl)]hexafluoropropane dianhydride, ethyleneglycol bis(anhydrotrimellitate), and 5-(2,5-dioxotetrahydro)-3-methyl-3-cyclohexene-1,2-dicarboxylic anhydride. Any of these tetracarboxylic acid dianhydrides can be used individually or in combination in any suitable ratio to form a polyimide described herein.

In some embodiments, the fully imidized polyimide mentioned herein is at least about 90% (e.g., at least about 95%, at least about 98%, at least about 99%, or about 100%) imidized.

In some embodiments, the at least one diamine includes a compound selected from the group consisting of a diamine of Structure (II);

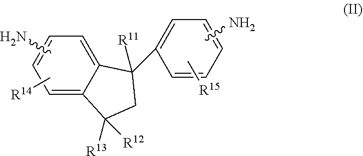

in which each of R¹¹, R¹², R¹³, R¹⁴ and R¹⁵ independently, is H, a substituted or unsubstituted C₁-C₆ linear or branched alkyl group, or C₅-C₇ cycloalkyl group.

Examples of the substituted or unsubstituted C₁-C₆ linear or branched alkyl groups in of R¹¹, R¹², R¹³, R¹⁴ and R¹⁵ include, but are not limited to, methyl, ethyl, propyl, isopropyl, butyl, isobutyl, t-butyl, amyl, hexyl, and 2-methylhexyl. Examples of the C₅-C₇ cycloalkyl group in of R¹¹, R¹², R¹³, R¹⁴ and R¹⁵ include, but are not limited to, cyclopentyl, cyclohexyl, and cycloheptyl.

Examples of preferred diamines (II) of this embodiment include, but are not limited to, 1-(4-aminophenyl)-1,3,3-trimethylindan-5-amine (alternative names including 4,4′-[1,4-phenylene-bis(1-methylethylidene)] bisaniline, 1-(4-aminophenyl)-1,3,3-trimethyl-2H-inden-5-amine, 1-(4-aminophenyl)-1,3,3-trimethyl-indan-5-amine, [1-(4-aminophenyl)-1,3,3-trimethyl-indan-5-yl]amine, and 1-(4-aminophenyl)-2,3-dihydro-1,3,3-trimethyl-1H-inden-5-amine), 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, and 5,7-diamino-1,1-dimethyl-4-ethylindan.

In some embodiments, the fully imidized polyimide may be partially fluorinated polyimide. Examples of suitable diamines that can be used to prepare the polymer of structure (I) include, but are not limited to 2,5-diaminobenzotrifluoride, 3,5-diaminobenzotrifluoride, 1,3-diamino-2,4,5,6-tetrafluorobenzene, 2,2′-bis(trifluoromethyl) benzidine, 3,3′-bis(trifluoromethyl) benzidine, 2,2-bis[4-(4-aminophenoxyphenyl)]hexafluoropropane, 2,2-bis(3-amino-4-methylphenyl)-hexafluoropropane, 2,2-bis(3-aminophenyl)-1,1,1,3,3,3-hexafluoropropane, 4,4′-diamino-2,2′-bis(trifluoromethyl) biphenyl, 1,4-bis(4′-amino-3′-trifluoromethylphenoxy)benzene, 1,1-bis[4′-(4″-amino-2″-trifluoromethylphenoxy)phenyl]cyclopentane, 1,1-bis[4′-(4″-amino-2″-trifluoromethylphenoxy)phenyl]cyclohexane and the like. Similarly, the example of fluorinated dianhydride is 2,2-[bis(3,4-dicarboxyphenyl)] hexafluoropropane dianhydride. Any of these fluorinated diamines can be used individually or in combination in any suitable ratio to form a polyimide described herein.

In another embodiments, the fully imidized polyimide is completely fluorine free polyimide polymer.

Examples of suitable diamines that can be used to prepare the polymer of fluorine free polyimide include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl) propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline) isopropylidene, bis(p-beta-amino-t-butylphenyl) ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy)phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene, H-fluorene-2,6-diamine, bis(aminopropyl)tetramethyldisiloxane (BATMS), 4,4′-methylenebis(2,6-diethylaniline), 4,4′-methylenebis(2,6-dimethylaniline), 4,4′-methylenebis(2,6-diisopropylaniline), 4,4′-methylenebis(2,6-dipropylaniline), 4,4′-methylenebis(2,6-di tert-butylaniline), bis(aminopropyl)tetraphenyldisiloxane, bis(4-aminophenoxy)dimethylsilane and the like. Any of these diamines can be used individually or in combination in any suitable ratio to form a polyimide described herein.

Examples of suitable dianhydrides that can be used to prepare the fluorine free polyimide include, but are not limited to, 1-(3′,4′-dicarboxyphenyl)-1,3,3-trimethylindan-5,6-dicarboxylic acid dianhydride, 1-(3′,4′-dicarboxyphenyl)-1,3,3-trimethylindan-6,7-dicarboxylic acid dianhydride, 1-(3′,4′-dicarboxyphenyl)-3-methylindan-5,6-dicarboxylic acid dianhydride, 1-(3′,4′-dicarboxyphenyl)-3-methylindan-6,7-dicarboxylic acid anhydride, pyromellitic dianhydride, benzene-1,2,3,4-tetracarboxylic dianhydride, 2,3,5,6-naphthalenetetracarboxylic acid dianhydride, 2,3,6,7-naphthalenetetracarboxylic acid dianhydride, 1,4,5,8-naphthalenetetracarboxylic acid dianhydride, phenanthrene-, 8,9,10-tetracarboxylic dianhydride, 3,4,9,10-perylenetetracarboxylic acid dianhydride, pyrazine-2,3,5,6-tetracarboxylic dianhydride, thiophene-2,3,4,5-tetracarboxylic dianhydride, 2,3,5,6-pyridinetetracarboxylic acid dianhydride, butane-1,2,3,4-tetracarboxylic acid dianhydride, 1,2,3,4-cyclopentanetetracarboxylic acid dianhydride, cyclobutane-1,2,3,4-tetracarboxylic acid dianhydride, cyclopentane-1,2,3,4-tetracarboxylic acid dianhydride, cyclohexane-1,2,4,5-tetracarboxylic acid dianhydride, norbornane-2,3,5,6-tetracarboxylic acid dianhydride, bicyclo[2.2.2]oct-7-ene-3,4,8,9-tetracarboxylic acid dianhydride, tetracyclo[4.4.1.0^{2,5}.0^{7,10}]undecane-1,2,3,4-tetracarboxylic acid dianhydride, 3,3′,4,4′-benzophenone tetracarboxylic dianhydride, 2,2′,3,3′-benzophenone tetracarboxylic dianhydride, 2,3,3′,4′-benzophenone tetracarboxylic dianhydride, 3,3′,4,4′-diphenylsulfone tetracarboxylic dianhydride, 2,2′,3,3′-diphenylsulfone tetracarboxylic dianhydride, 2,3,3′,4′-diphenylsulfone tetracarboxylic dianhydride, 3,3′,4,4′-diphenylether tetracarboxylic dianhydride, 2,2′,3,3′-diphenylether tetracarboxylic dianhydride, 2,3,3′,4′-diphenylether tetracarboxylic dianhydride and 5-(2,5-dioxotetrahydro)-3-methyl-3-cyclohexene-1,2-dicarboxylic anhydride. Any of these tetracarboxylic acid dianhydrides can be used individually or in combination in any suitable ratio to form a polyimide described herein.

In some embodiments, the weight average molecular weight of the fully imidized polyimide is at least about 20,000 Daltons (e.g., at least about 25,000 Daltons, at least about 30,000 Daltons, at least about 35,000 Daltons, at least about 40,000 Daltons, at least about 45,000 Daltons, at least about 50,000 Daltons, or at least about 55,000 Daltons) and/or at most about 100,000 Daltons (e.g., at most about 95,000 Daltons, at most about 90,000 Daltons, at most about 85,000 Daltons, at most about 80,000 Daltons, at most about 75,000 Daltons, at most about 70,000 Daltons, at most about 65,000 Daltons, or at most about 60,000 Daltons).

In some embodiments, the fully imidized polyimide is prepared by reaction of at least one diamine with at least one tetracarboxylic acid dianhydride. In some embodiments, the resulting polymer is soluble in the organic solvent of this disclosure to facilitate the formation of a dielectric film, such as a dielectric film with a planarized surface (e.g., the difference in the highest and lowest points on a top surface of the dielectric film is less than about 2 microns). Examples of fully imidized polyimides are known in the art and have been described, e.g., in U.S. Application Publication No. 2019/0077913, the entire contents of which are hereby incorporated by reference.

Methods to synthesize end-capped and non-endcapped PI precursor polymers are well known to those skilled in the art. Examples of such methods and PI precursor polymers are disclosed in, e.g., U.S. Pat. Nos. 2,731,447, 3,435,002, 3,856,752, 3,983,092, 4,026,876, 4,040,831, 4,579,809, 4,629,777, 4,656,116, 4,960,860, 4,985,529, 5,006,611, 5,122,436, 5,252,534, US5,4789,15, U.S. Pat. Nos. 5,773,559, 5,783,656, 5,969,055, 9,617,386, and US Application Publication No. US2004/0265731, US2004/0235992, and US2007/0083016, the entire contents of which are hereby incorporated by reference.

In some embodiments, the fully imidized polyimide described herein can be an alkali soluble polyimide which has at least one (e.g., two or three) functional group such as a carboxylic acid group, a hydroxyl group (e.g., a phenolic hydroxyl group), a sulfonic acid group, or a thiol group (e.g., at one end of a main chain or both, or at a side chain of the polymer). The term “alkali soluble” used herein means that the solubility in a 2.38 weight percent aqueous tetramethylammonium hydroxide solution at 25° C. is not less than about 0.1 g/100 mL.

In some embodiments, the polymer resins suitable for the dielectric film forming compositions described herein can include at least one (e.g., two, three, or four) other dielectric polymer, such as a dielectric polymer containing an epoxy resin, a novolac resin, or a mixture of epoxy and novolac resins, a polybenzoxazole (PBO) precursor polymer, or a mixture thereof.

Examples of suitable epoxy resins that can be used as dielectric film materials are known to those skilled in the art and include those disclosed in, e.g., U.S. Pat. No. 4,882,245 and U.S. Application Publication No. 2006/0257785, the entire contents of which are hereby incorporated by reference.

Examples of suitable Novolac polymers described herein include those containing at least one photoactive o-quinonediazide compound and are known to those skilled in the art. Example of such Novolac polymers is disclosed in U.S. Pat. Nos. 5,413,894; 5,306,594; 4,959,292, 8,334,092; and 8,492,067; and U.S. Application Publication No. 2012/0296053 and 2012/0052438; the entire contents of which are hereby incorporated by reference.

In some embodiments, the resins in the dielectric film forming compositions described herein can include at least one (e.g., two or three) cyclic rubber. In some embodiments, the cyclized rubber is selected from a group of cyclized polydienes. In some embodiments, the cyclized polydienes include homopolymers of conjugated dienes such as isoprene, butadiene, and pentadiene. In other embodiments, the cyclized polydienes include copolymers of such conjugated dienes with olefins, styrene, or acrylates. In some embodiments, cyclization of rubber occurs under influence of heat, light, ultraviolet or nuclear radiation and/or in the presence of cation-donor catalysts (e.g., mineral acids, organic acids, or Lewis's acids). For example, two neighboring polymer structural units can participate in a cis olefin catalyzed cyclization to create a monocyclic structure, whilst one double bond will vanish. In general, bi- or tri-cyclic structures are created in later cyclization stages. Gradually, the unsaturation and elasticity are reduced as the result of successive cyclization of cis polydiene, and their toughness is increased. The cyclization is generally more efficient in polyisoprene than in polybutadiene. By controlling temperature, catalyst concentration and reaction time, a cyclization degree of from about 50% to about 95% can be achieved. Examples of such cyclization methods have been described in, e.g., U.S. Pat. Nos. 4,678,841 and 4,248,986, and European Patent No. 0063043, the contents of which are hereby incorporated by reference. These cyclized rubbers may be used alone or in combination of two or more kinds thereof. In some embodiments, the cyclized rubber is polyisoprene.

In some embodiments, the resins in the dielectric film forming compositions described herein can include at least one (e.g., two or three) cyanate ester compound (e.g., a cyanate ester compound having at least two cyanate groups in one molecule).

In some embodiments, the cyanate ester compounds described herein can have Structure (III):

Ar—(O—C≡N)ₘ (III)

wherein m is an integer of at least 2 (m≥2) and Ar is a substituted or unsubstituted aromatic organic group wherein the cyanate ester groups are directly bonded to said substituted or unsubstituted aromatic organic group. In some embodiments, the aromatic organic group described above is optionally substituted by at least one (e.g., two or three) C₁-C₄ alkyl, halogen, C₁-C₄ haloalkyl, —OR′, —OC(O) R′, or —COOR′, where R′ is H, C₁-C₄ alkyl, C₅-C₁₂ cycloalkyl, C₆-C₁₈ aryl, or C₆-C₁₈ heteroaryl.

In some embodiments, the cyanate ester compounds described herein can have Structure (IV):

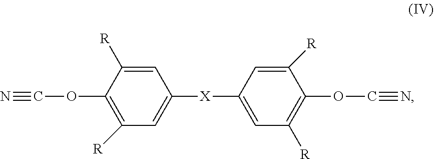

wherein R is a hydrogen atom, a C₁-C₃ alkyl group, a fully or partially halogen substituted C₁-C₃ alkyl group, or a halogen atom; X is a single bond, an O or S atom, (C═O)—, —(C═O)—O—, —O—(C═O)—, —(S═O)—, —(SO₂)—, —CH₂CH₂—O— group, substituted or unsubstituted C₁-C₁₀ alkylene group, partially or fully fluoro substituted C₁-C₄ alkylene group, substituted or unsubstituted C₃-C₁₀ cycloalkylene group.

Specific examples of suitable cyanate ester compounds can include 2-bis(4-cyanatophenyl) propane, hexafluorobisphenol A dicyanate, bis(4-cyanate-3,5-dimethylphenyl) methane, 1,3-bis(4-cyanatephenyl-1-(methylethylidene))benzene, bis(4-cyanatephenyl)thioether, bis(4-cyanatephenyl) ether, and a polyfunctional cyanate resin derived from a phenol novolac, cresol novolac, or dicyclopentadiene-containing phenol resin. Other examples of such cyanate ester compounds have been described in, e.g., U.S. Pat. Nos. 3,595,900, 4,894,414, and 4,785,034 and U.S. Application Publication Nos. 2022/0002463 and 2022/0127459, the contents of which are hereby incorporated by reference. In some embodiments, although the weight average molecular weight of a cyanate ester resin or polymer is not particularly limited, it is from at least about 500 Daltons (e.g., at least about 600 Daltons) to at most about 4,500 Daltons (e.g., at most about 3,000 Daltons).

Without wishing to be bound by theory, it is believed that the cyanate ester compound can be cyclized and/or crosslinked thermally or under irradiation (e.g., with or without a catalyst) to form an interpenetrating network with the dielectric polymer in the dielectric film forming compositions described herein. Further, without wishing to be bound by theory, it is believed that including a cyanate ester compound in a dielectric film forming composition described herein can lower the dielectric constant (K) and/or dissipation factor (DF) of the film formed from the composition.

In some embodiments, the amount of the resin or dielectric polymer is at least about 0.1 wt % (e.g., at least about 0.5 wt %, at least about 1 wt %, at least about 2 wt %, at least about 5 wt %, at least about 10 wt %, at least about 15 wt %, or at least about 20 wt %) and/or at most or about 55 wt % (e.g., at most about 50 wt %, at most about 45 wt %, at most about 40 wt %, at most about 35 wt %, at most about 30 wt %, at most about 25 wt %, at most about 20 wt %, at most about 15 wt %, or at most about 10 wt %) of the solid weight of the dielectric film forming compositions described herein.

Log P is an important molecular physical property that influences a wide range of parameters in formulations. Log P is the measure of the preference of a compound to be dissolved in either water or an organic solvent (such as octanol) when uncharged. More technically, it is the logarithm of the partition coefficient (P) of a molecule between an aqueous and lipophilic phase. Log P predicts the partition coefficient, a measure of hydrophobicity, from structure.

The log P value is a constant defined in the following manner:

Log P=log 10 (Partition Coefficient organic)/(Partition Coefficient, water), P=[organic]/[aqueous]

Where [ ] indicates the concentration of solute in the organic and aqueous partition.

A negative value for log P means the compound has a higher affinity for the aqueous phase (it is more hydrophilic); when log P=0 the compound is equally partitioned between the lipid and aqueous phases; a positive value for log P denotes a higher concentration in the lipid phase (i.e., the compound is more lipophilic). Log P=1 means there is a 10:1 partitioning in organic: aqueous phases.

Although log P is a constant, its value is dependent on the choice of the organic partitioning solvent and, to a lesser degree, on the conditions of measurement. ACD/Labs' log P algorithms specifically calculate partitioning between octan-1-ol and water—the most commonly used system.

In some embodiments, the dielectric film forming compositions described herein can optionally include at least one (e.g., two, three, or four) hydrophobic multifunctional (meth)acrylate crosslinker where the log P (octanol/water partition coefficient) value of the hydrophobic multifunctional (meth)acrylate crosslinker is 0.5 or more and less than 8.0. In some embodiments, the hydrophobic multifunctional (meth)acrylate crosslinker can include an ethylenically unsaturated polymerizable compound (e.g., an ethylenically unsaturated photopolymerizable compound), a metal-containing (meth)acrylate compound, or mixtures thereof.

In some embodiments, the dielectric film forming compositions described herein can optionally include at least one (e.g., two, three, or four) hydrophobic multifunctional (meth)acrylate crosslinker where the log P (octanol/water partition coefficient) value of the hydrophobic multifunctional (meth)acrylate crosslinker is 0.5 or more and less than 7.0. In some embodiments, the dielectric film forming compositions described herein can optionally include at least one (e.g., two, three, or four) hydrophobic multifunctional (meth)acrylate crosslinker where the log P (octanol/water partition coefficient) value of the hydrophobic multifunctional (meth)acrylate crosslinker is 0.5 or more and less than 5.0. The hydrophobic multifunctional (meth)acrylate crosslinker means a compound having one or more unsaturated(meth)acryloyloxy groups in the molecule. One typical example of the (meth)acrylate compound is (meth)acrylic acid ester.

When the log P value is too low, it affects the stability of the film forming properties of photosensitive composition and tends to nonuniform film. In addition, when the log P value is too high, separation of the photopolymerizable compound (B) and film forming resin (A) may occur, causing the resin to be aggregated.

In some embodiments, the hydrophobic multifunctional (meth)acrylate crosslinker described herein can include an ethylenically unsaturated polymerizable compound containing at least two (meth)acrylate groups. In some embodiments, the crosslinker is selected from the group consisting of 1,6-hexanediol di(meth)acrylate, tetraethyleneglycol di(meth)acrylate, 1,12-dodecanediol di(meth)acrylate, 1,3-butylene glycol di(meth)acrylate, 1,4-butanediol di(meth)acrylate, cyclohexane dimethanol di(meth)acrylate, polyethylene glycol di(meth)acrylate, propoxylated (3)glycerol tri(meth)acrylate, ethoxylated bisphenol-A-di(meth)acrylate, trimethylolpropane tri(meth)acrylate, ditrimethylolpropane tetra(meth)acrylate, pentaerythritol tri(meth)acrylate, pentaerythritol tetra(meth)acrylate, dipentaerythritol penta-/hexa-(meth)acrylate, isocyanurate tri(meth)acrylate, bis(2-hydroxyethyl)-isocyanurate di(meth)acrylate, 1,3-butanediol tri(meth)acrylate, 1,4-butanediol tri(meth)acrylate, neopentyl glycol di(meth)acrylate, (meth)acrylate modified-urea-formaldehyde resins, (meth)acrylate modified melamine-formaldehyde resins, and (meth)acrylate modified cellulose. Other examples of such compounds are disclosed in, e.g., U.S. Pat. Nos. 10,036,952 and 10,563,014, and U.S. Application Publication No. 2015/0219990, EP U.S. Pat. No. 3,492,982; the entire contents of which are hereby incorporated by reference.

The example of Log P of hydrophobic multifunctional (meth)acrylate crosslinker are tris(2-hydroxy ethyl) isocyanurate triacrylate (Log P-0.26), pentaerythritol triacrylate (Log P 0.56), tetraethylene glycol dimethacrylate (Log P 1.45), tripropylene glycol diacrylate (Log P 1.75), dipropylene glycol diacrylate (Log P 1.76), neopentyl glycol diacrylate (Log P 1.86), 1,4-butanediol diacrylate (Log P 2.2), ethylene glycol dimethacrylate (Log P 2.78) 1,6-hexanediol diacrylate (Log P 2.96), 2-(tricyclo[5.2.1.02,6] dec-3-en-8-yloxy)ethyl acrylate (Log P 3.01), trimethylolpropane trimethacrylate (Log P 3.15), hydroxyl pivalic neopentyl glycol diacrylate (Log P 3.56), bisphenol A (EO) 2 diacrylate (Log P 5.89), pentaerythritol tetraacrylate (Log P-0.13), tetraethylene glycol diacrylate (Log P 0.34), triethylene glycol diacrylate (Log P 0.70), trimethylolpropane triacrylate (Log P 1.50), triethylene glycol dimethacrylate (Log P 1.81), 1,6-hexanediol diacrylate (Log P 2.35), dipentaerythritol hexaacrylate (Log P 2.47), dipentaerythritol pentaacrylate (Log P 2.55), trimethylolpropane (EO) 3 triacrylate (Log P 2.79), trimethylolpropane (EO) 9 trimethacrylate (Log P 2.79), neopentyl glycol dimethacrylate (Log P 2.96), 1,6-hexanediol dimethacrylate, (Log P 4.06), tricyclodecane dimethanol diacrylate (Log P 4.22), ditrimethylolpropane tetraacrylate (Log P 4.26), 1,9-nonanediol diacrylate (Log P 4.55) and 1,10-decanediol diacrylate (Log P 5.08).

In some embodiments, the crosslinker described herein can be a metal-containing (meth)acrylate (MCA) compound. As used herein, the term “(meth)acrylate” refers to both acrylate compounds and methacrylate compounds. Examples of suitable MCAs include, but are not limited to, titanium tetra(meth)acrylate, zirconium tetra(meth)acrylate, hafnium tetra(meth)acrylate, titanium butoxide tri(meth)acrylate, titanium(meth)acryloxyethylacetoacetate triisopropoxide, titanium tris(2-ethylhexanoate) (carboxyethyl (meth)acrylate), titanium tetra(carboxyethyl (meth)acrylate), zirconium tetra(carboxyethyl (meth)acrylate), hafnium tetra(carboxyethyl (meth)acrylate), titanium butoxide tri (carboxyethyl (meth)acrylate), titanium dibutoxide di(carboxyethyl (meth)acrylate), titanium tributoxide (carboxyethyl (meth)acrylate), titanium oxide di(carboxyethyl (meth)acrylate), zirconium butoxide tri (carboxyethyl (meth)acrylate), zirconium dibutoxide di(carboxyethyl (meth)acrylate), zirconium tributoxide (carboxyethyl (meth)acrylate), zirconium oxide di(carboxyethyl (meth)acrylate), zirconium bis(2-ethylhexanoate)di(carboxyethyl (meth)acrylate Other examples of such compounds are disclosed in, e.g., U.S. Application Publication No. 2021/104398; the entire contents of which are hereby incorporated by reference.

In some embodiments, the crosslinker described herein can be in an amount of from at least about 0.5 wt % (e.g., at least about 1 wt %, at least about 2 wt %, at least about 3 wt %, at least about 4 wt %, at least about 5 wt %, at least about 6 wt %, at least about 7 wt %, at least about 8 wt %, at least about 9 wt %, at least about 10 wt %) to at most about 35 wt % (e.g., at most about 30 wt. %, at most about 28 wt. %, at most about 26 wt. %, at most about 24 wt %, at most about 22 wt %, at most about 20 wt %, at most about 18 wt %, at most about 16 wt %, at most about 15 wt %, at most about 14 wt %, at most about 12 wt %, at most about 10 wt %, at most about 8 wt %, at most about 6 wt %, or at most about 5 wt %) of the solid weight of a dielectric film forming composition described herein.

The dielectric film forming compositions described herein can optionally contain at least one (e.g., two, three, or four) radical initiator. As used herein, a radical initiator refers to a compound capable of generating free radicals that can initiate radical polymerization or crosslinking upon heating or irradiation with light at a certain wavelength range (e.g., from about 150 nm (e.g., about 157 nm) or about 600 nm). In some embodiments, the wavelength range is selected such that the radical initiator has absorption and the radically polymerizable monomer does not have substantial absorption. A photo-radical initiator (also referred to herein as a photoinitiator) and a thermal-radical initiator (also referred to herein as a thermal initiator) are examples of a radical initiator. In some embodiments, a photo-radical initiator is preferable.

In some embodiments, the amount of the radical initiator (e.g., a photoinitiator) is from at least about 0.1 wt % (e.g., at least about 0.2 wt %, at least about 0.5 wt %, at least about 0.8 wt %, at least about 1 wt %, at least about 1.5 wt %, at least about 2 wt %, at least about 3 wt %, at least about 4 wt %, or at least about 5 wt %) to at most about 10 wt % (e.g., at most about 9 wt %, at most about 8 wt %, at most about 7 wt %, at most about 6 wt %, at most about 5 wt %, at most about 4 wt %, at most about 3 wt %, at most about 2 wt %, or at most about 1 wt %) of the solid weight of a dielectric film forming composition described herein.

In some embodiments, a photoinitiator has photosensitivity to rays ranging from an ultraviolet ray region to a visible region. In some embodiments, the photoinitiator can be an activator which produces a free radical by some action with a photo-excited sensitizer. In some embodiments, the photoinitors are selected from group consisting of oxime ester, titanocene, acyl germanium compound, peroxide, and their mixture thereof.

One example of a photoinitiator is an oxime ester of structure (V),

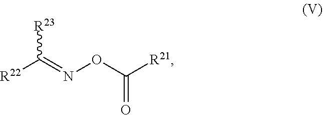

wherein each of R²¹ and R²², independently, is a substituted or unsubstituted C₁-C₁₂ alkyl, a substituted or unsubstituted C₄-C₁₈ cycloalkyl, a substituted or unsubstituted C₆-C₂₂ aryl, or a substituted or unsubstituted C₆-C₂₂ heteroaryl; and R²³ is a UV absorbing functional group (e.g., a substituted or unsubstituted C₆-C₂₂ aryl or a substituted or unsubstituted C₆-C₂₂ heteroaryl). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O) R′, or —COOR′, where R′ is H, C₁-C₄ alkyl, C₅-C₁₂ cycloalkyl, C₆-C₁₈ aryl, or C₆-C₁₈ heteroaryl.

Examples of oxime esters of formula (II) include, but are not limited to,

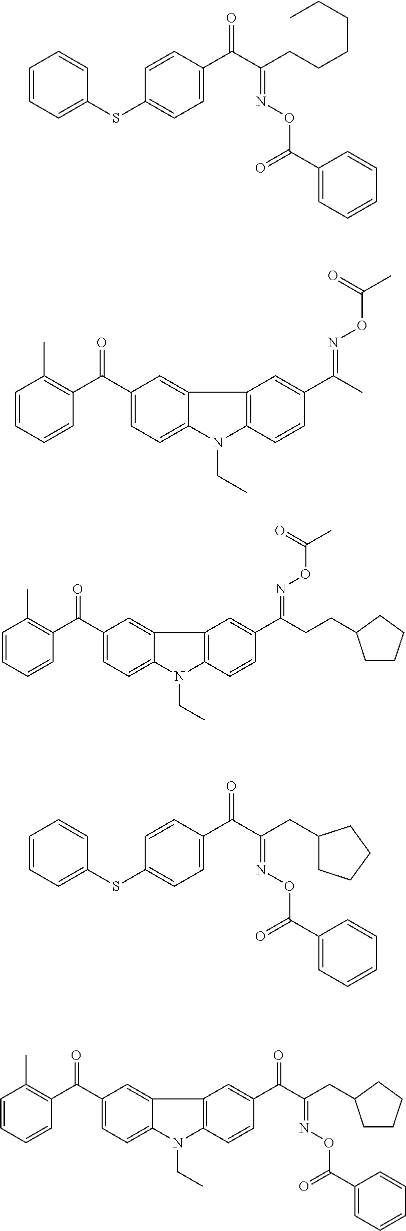 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCn1c2ccc(C(=O)c3ccccc3C)cc2c2cc(/C(CCC3CCCC3)=N/OC(C)=O)ccc21 ; O=C(O/N=C(\CC1CCCC1)C(=O)c1ccc(Sc2ccccc2)cc1)c1ccccc1 ; CCn1c2ccc(C(=O)/C(CC3CCCC3)=N/OC(=O)c3ccccc3)cc2c2cc(C(=O)c3ccccc3C)ccc21]

Another example of a photoinitiator is an organic titanocene compound of structure (VI):

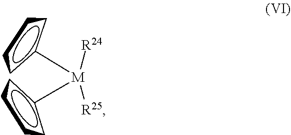

wherein M is selected from the group consisting of a titanium atom, a zirconium atom, and a hafnium atom; and each of R¹⁴ and R¹⁵, independently, is selected from the group consisting of substituted or unsubstituted C₁-C₁₂ alkyl, substituted or unsubstituted C₄-C₁₈ cycloalkyl, substituted or unsubstituted C₆-C₂₂ aryl, substituted or unsubstituted C₆-C₂₂ heteroaryl, a substituted or unsubstituted C₆-C₂₂ heteroaryl, or a substituted or unsubstituted alkylsulfonyloxy group (e.g., a substituted or unsubstituted C₁-C₁₂ alkylsulfonyloxy group). In some embodiments, the alkyl, cycloalkyl, aryl, or heteroaryl described above is optionally substituted by at least one (e.g., two or three) C₁-C₄ alkyl, halogen, C₁-C₄ haloalkyl, —OR′, —OC(O) R′, or —COOR′, where R′ is H, C₁-C₄ alkyl, C₅-C₁₂ cycloalkyl, C₆-C₁₈ aryl, or C₆-C₁₈ heteroaryl.

Commercial examples of photoinitiators include, but are not limited to, IRGACURE-784, IRGACURE OXE 01, IRGACURE OXE 02, IRGACURE OXE 03, IRGACURE OXE 04, and IRGACURE OXE 05 available from BASF; ADEKA OPTOMER N-1919, ADEKA ARKLS NCI-831, and ADEKA ARKLS NCI-930 available from ADEKA Corporation. Examples of other photoinitiators are disclosed in, e.g., EP patent numbers 3,492, 982, the entire contents of which are hereby incorporated by reference.

Examples of thermal initiators include, but are not limited to, benzoyl peroxide, cyclohexanone peroxide, lauroyl peroxide, tert-amyl peroxybenzoate, tert-butyl hydroperoxide, di(tert-butyl) peroxide, dicumyl peroxide, cumene hydroperoxide, succinic acid peroxide, di(n-propyl) peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, acyl germanium compound may use as photoinitiator. Suitable examples of the compounds of acyl germanium compound, but not limited to, (2,4,6-trimethylbenzoyl)triethylgermanium, (2,4,6-trimethylbenzoyl)tripropylgermanium, (2,4,6-trimethylbenzoyl)tributylgermanium, (2,6-dimethoxybenzoyl)triethylgermanium, (2.6-dimethoxybenzoyl)tripropylgermanium, (2,6-dimethoxybenzoyl)tributylgermanium, bisbenzoyldiethylgermanium, bisbenzoyldipropylgermanium, bis(4-methoxybenzoyl) diethylgermanium, bis(2,4,6-trimethylbenzoyl) diethylgermanium, trisbenzoylethylgermanium, tris(2,4,6-trimethylbenzoyl)ethylgermanium and the like. A commercial example of an acyl germanium compound is Ivocerin (i.e., bis(4-methoxybenzoyl) diethylgermanium). Other examples of such acyl germenium compounds are disclosed in, e.g., U.S. Pat. Nos. 7,605,190 and 9,532,930, the entire contents of which are hereby incorporated by reference.

In some embodiments, the dielectric film forming compositions described herein can include at least one (e.g., two, three, or four) photosensitizer different from the acyl germanium compound, where the photosensitizer can absorb light in the wavelength range of from about 150 nm to about 600 nm (e.g., at about 405 nm). Examples of suitable photosensitizers that can be used in the dielectric film forming composition include benzophenone compounds, thioxanthone compounds, anthraquinone compounds, anthracene compounds, coumarine compounds, and mixtures thereof. Specific examples of photosensitizers include, but are not limited to, 9-methylanthracene, 9,10-dibutoxyanthracene, 9,10-diethoxyanthracene, anthracenemethanol, acenaphthylene, thioxanthone, methyl-2-naphthyl ketone, 4-acetylbiphenyl, and 1,2-benzofluorene. Examples of other photosensitizers are disclosed in, e.g., U.S. Application Publication No. 2022/0171285, the entire contents of which are hereby incorporated by reference. In some embodiments, the acyl germanium compounds described herein can serve as a photosensitizer.

In some embodiments, the amount of a photosensitizer other than an acyl germanium compound is from at least about 0.01 wt % (e.g., at least about 0.05 wt %, at least about 0.1 wt %, or at least about 0.5 wt %) to at most about 1 wt % (e.g., at most about 0.8 wt %, at most about 0.6 wt %, at most about 0.5 wt %, at most about 0.4 wt %, at most about 0.2 wt %, or at most about 0.1 wt %) of the solid weight of a dielectric film forming composition described herein.

In some embodiments, the dielectric film forming compositions described herein can further include an organic solvent or a mixture (e.g., two, three, or four) of organic solvents. In another embodiments, the solvents are selected from group consisting of alkylene carbonates, lactones, cycloketones, linear ketones, alkyl esters; alkyl ester alcohol, alkyl ether alcohols, alkyl ether ester, glycol ester; glycol ether, cyclic ether, pyrrolidone, and dialkylsulfoxide and their mixture thereof. Examples of organic solvents suitable for the dielectric film forming compositions described herein include, but are not limited to, alkylene carbonates such as ethylene carbonate, propylene carbonate, butylene carbonate, and glycerine carbonate; lactones such as gamma-butyrolactone, ε-caprolactone, γ-caprolactone and γ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; ether ester such as (tetrahydrofuran-2-yl)methyl acetate, methyl-3-methoxypropionate, ethyl-3-ethoxypropionate and 3-methoxy butyl acetate; glycol esters such as propylene glycol methyl ether acetate; glycol ethers such as propylene glycol methyl ether (PGME); cyclic ethers such as tetrahydrofuran (THF); pyrrolidones such as N-methyl-2-pyrrolidone, N-ethyl-2-pyrrolidone or N-butyl-2-pyrrolidone or TamiSolve™ NxG; and dialkyl sulfoxide such as dimethyl sulfoxide.

The examples of Log P of solvent are γ-butyrolactone (Log P-0.76), cyrene (Log P-0.71), propylene carbonate (Log P-0.41), γ-valerolactone (Log P-0.27), ethyl lactate (Log P-0.19), cyclopentanone (Log P 0.2), furfuryl alcohol (LogP 0.2), 3-methoxybutyl acetate (Log P 0.75), cyclohexanone (Log P 0.76), TamiSolve™ NxG (Log P 1.2), Dottisol (Log P-0.65).

In some embodiments, the total amount of the solvent is at least about 20 wt % (e.g., at least about 25 wt %, at least about 30 wt %, at least about 35 wt %, at least about 40 wt %, at least about 45 wt %, at least about 50 wt %, at least about 55 wt %, at least about 60 wt %, or at least about 65 wt %) and/or at most about 98 wt % (e.g., at most about 95 wt %, at most about 90 wt %, at most about 85 wt %, at most about 80 wt %, at most about 75 wt %, at most about 70 wt %, or at most about 60 wt %) of the total weight of the dielectric film forming compositions described herein.

In some embodiments, the dielectric film forming compositions described herein optionally includes at least one (e.g., two, three, or four) filler (such as an inorganic filler or an inorganic particle). In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. Preferably, the inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 wt % (e.g., at least about 2 wt %, at least about 5 wt %, at least about 8 wt %, or at least about 10 wt %) and/or at most about 30 wt % (e.g., at most about 25 wt %, at most about 20 wt %, or at most about 15 wt %) of the solid weight of the dielectric film forming compositions described herein.

In some embodiments, the dielectric film forming compositions described herein can optionally further include at least one (e.g., two, three, or four) adhesion promoter. Suitable adhesion promoters are described in “Silane Coupling Agent” Edwin P. Plueddemann, 1982 Plenum Press, New York. Examples of such adhesion promoters are disclosed in, e.g., U.S. Pat. Nos. 10,036,952 and 10,563,014, and U.S. Application Publication No. 2015/0219990, and EP Patent No. 3,492, 982; the entire contents of which are hereby incorporated by reference.

In some embodiments, the amount of the optional adhesion promoter is at least about 0.5 wt % (e.g., at least about 0.8 wt %, at least about 1 wt %, or at least about 1.5 wt %) and/or at most about 4 wt % (e.g., at most about 3.5 wt %, at most about 3 wt %, at most about 2.5 wt %, or at most about 2 wt %) of the solid weight of the dielectric film forming compositions described herein.

In some embodiments, the dielectric film forming compositions described herein can optionally contain at least one (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the entire contents of which are hereby incorporated by reference.

In some embodiments, the amount of the surfactant is at least about 0.005 wt % (e.g., at least about 0.01 wt % or at least about 0.1 wt %) and/or at most about 1 wt % (e.g., at most about 0.5 wt % or at most about 0.2 wt %) of the solid weight of the dielectric film forming compositions described herein.

In some embodiments, the dielectric film forming compositions described herein can optionally contain at least one (e.g., two, three, or four) corrosion inhibitor. Examples of suitable corrosion inhibitors include triazole compounds, imidazole compounds and tetrazole compounds. Triazole compounds can include triazoles, benzotriazoles, substituted triazoles, and substituted benzotriazoles. The dielectric film forming compositions comprising corrosion inhibitors prevent corrosion and discoloration of copper or copper alloy when the photosensitive layer used on top of the copper or copper alloy. he corrosion inhibitor additive play a significant role in improving HAST stability of TEG chip by effectively binding in copper. Examples of suitable corrosion inhibitors include Structure (VII), (VIII), (IX), (X), and (XI);

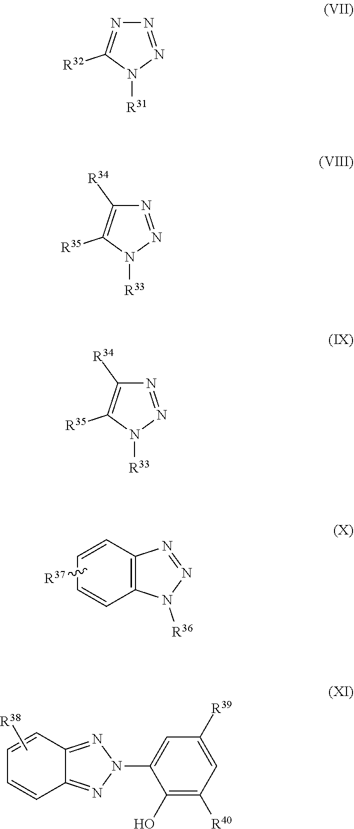

wherein R³¹, R³², R³³, R³⁴, R³⁵, R³⁶ are a hydrogen atom, a functional or unfunctional C₁-C₆ alkyl group, t-alkyl of 4 to 6 carbons, or a functional or unfunctional C₆-C₂₂ aromatic group; R³⁷ and R³⁸ are a hydrogen atom, a C₁-C₄ alkyl group, t-alkyl of 4 to 6 carbons, or an allyl group; R³⁹ are a hydrogen, a C₁-C₄ alkyl group, or polymerizable group; R⁴⁰ is a hydrogen or halogen;

Examples of tetrazole compound of structure (VII) include 1-H-tetrazole, 5-methyl-1H-tetrazole, 5-phenyl-1H-tetrazole, 5-(ethylthio)-1H-tetrazole, 5-(benzylthio)-1H-tetrazole, ethyl 1H-tetrazole-5-acetate, ethyl 1H-tetrazole-5-carboxylate, 5-amino-1H-tetrazole, 1-phenyl-5-mercapto-1H-tetrazole, 5,5′-bis-1H-tetrazole, 1-methyl-5-ethyltetrazole, 1-methyl-5-mercaptotetrazole, 1-carboxymethyl-5-mercaptotetrazole, 5-amino-1H-tetrazole and the like.

Examples of triazole compounds of Structure (VIII) and (IX) include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups.

Specific examples of triazole include 1,2,4-triazole, 1,2,3-triazole, 5-methyl-1,2,4-triazole, 3-amino-5-mercapto-1,2,4-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, and the like.

Examples of benzotriazole of Structure (X) include 1-H benzotriazole, tolyltriazole, 5-phenyl-benzotriazole, 5-nitro-benzotriazole, hydroxybenzotriazole, 2-(5-amino-pentyl)-benzotriazole, 5-phenylthiol-benzotriazole, 5-methyl-1H-benzotriazole, 4-methyl-1H-benzotriazole, 4-carboxy-1H-benzotriazole, 5-carboxy-1H-benzotriazole, and the like. Examples of benzotriazole of Structure (XI) include 2-hydroxy-5-acrylyloxyphenyl-2H-benzotriazoles, 2-(5-methyl-2-hydroxyphenyl)benzotriazole, 2-(3-t-butyl-phenyl) 5-methyl-2-hydroxy benzotriazole, 2-(3,5-di-t-amyl-2-hydroxyphenyl)benzotriazole, 2-hydroxy-3-chloro-5-acrylyloxyphenyl-2H-benzotriazoles and the like.

Examples of imidazole include, but are not limited to, 2-alkyl-4-methyl imidazole, 2-phenyl-4-alkyl imidazole, 2-methyl-4 (5)-nitroimidazole, 5-methyl-4-nitroimidazole, 4-Imidazolemethanol hydrochloride, and 2-mercapto-1-methylimidazole.

The amount of the optional corrosion inhibitor, if employed, is at least about 0.1 wt % (e.g., at least about 0.2 wt % or at least about 0.5 wt %) and/or at most about 3.0 wt % (e.g., at most about 2.0 wt % or at most about 1.0 wt %) of the solid weight of the dielectric film forming compositions described herein. The amount of corrosion inhibitor is more than the range, the storage stability is reduced, the amount of corrosion inhibitor is less than the above range, voids between the copper or copper alloy surface is likely to occur. The dielectric film forming compositions contain at least one corrosion inhibitor of log P from about-1.0 to about 6. When the log P value of corrosion inhibitor is too low, it affects the stability of the film forming properties of photosensitive composition and tends to nonuniform film. In addition, when the log P value corrosion inhibitor is too high, separation of the photopolymerizable compound (B) and film forming resin (A) may occur, causing the resin to be aggregated.

In some embodiments, the dielectric film forming compositions described herein include at least one (e.g., two, three, or four) corrosion inhibitor where the log P (octanol/water partition coefficient) value of the corrosion inhibitor compound is-0.8 or more and less than 5. In some embodiments, the dielectric film forming compositions described herein include at least one (e.g., two, three, or four) corrosion inhibitor compound where the log P (octanol/water partition coefficient) value of the corrosion inhibitor compound is-0.6 or more and less than 3.0.

The example of corrosion inhibitor with Log P value are 1H-tetrazole (Log P-0.6), 5-(ethylthio)-1H-tetrazole (Log P 0.6), 5-(benzylthio)-1H-tetrazole (Log P 1.574), 5-phenyltetrazole (Log P 1.91), ethyl 1H-tetrazole-5-acetate (Log P 0.03), ethyl 1H-tetrazole-5-carboxylate (Log P-0.1), 5-methyl-1H-benzotriazole (Log P 1.8), 3-amino-1,2,4-triazole (Log P-1.25), 3,5-diamino-1,2,4-triazole, (Log P-1.61), 1H-benzotriazole (Log P 1.34), 2-hydroxy-5-acrylyloxyphenyl-2H-benzotriazole (Log P 5.16).

In some embodiments, the dielectric film-forming compositions described herein include other optional components, such as one or more (e.g., two, three, or four) dyes, pigments, plasticizers, or antioxidants. Examples of such components have been described, e.g., in U.S. Application Publication No. 2022/0127459, the entire contents of which are hereby incorporated by reference.

In some embodiments, the dielectric film-forming compositions described herein are completely fluorine-free compositions wherein the fully imidized polyimides, solubility switching compounds, photoinitiators, sensitizers, adhesion promoters, surfactants, solvents, corrosion inhibitors and additives are completely fluorine free material.

In some embodiments, a dielectric film can be prepared from a dielectric film forming composition described herein by a method including the steps of: (a) coating the dielectric film forming composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods for preparation of the dielectric film include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In case of coating methods (1)-(11), the dielectric film forming composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments, the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns).

In some embodiments, when the dielectric film forming composition is photosensitive, the method to prepare a patterned photosensitive dielectric film includes converting the photosensitive dielectric film into a patterned dielectric film by a lithographic method. In such cases, the conversion can include exposing the photosensitive dielectric film to high energy radiation (such as electron beams, ultraviolet light, and X-ray) using a patterned mask.

After the exposure, the dielectric film can be heat treated from at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by use of an organic developer. Examples of such developers can include, but are not limited to, suitable organic solvents such as gamma-butyrolactone (GBL), gamma-valerolactone, cyrene, 2-methyl tetrahydrofuran, dimethyl sulfoxide (DMSO), N,N-diethylacetamide, methyl ethyl ketone (MEK), methyl isobutyl ketone (MIBK), 2-heptanone, cyclopentanone (CP), cyclohexanone, n-butyl acetate (nBA), propylene glycol methyl ether acetate (PGMEA), propylene glycol methyl ether (PGME), ethyl lactate (EL), propyl lactate, 3-methyl-3-methoxybutanol, tetralin, isophorone, ethylene glycol monobutyl ether, diethylene glycol monoethyl ether, diethylene glycol monoethyl ether acetate, diethylene glycol dimethyl ether, diethylene glycol methylethyl ether, triethylene glycol monoethyl ether, dipropylene glycol monomethyl ether, methyl 3-methoxypropionate, ethyl 3-ethoxypropionate, diethyl malonate, ethylene glycol, 1,4:3,6-dianhydrosorbitol, isosorbide dimethyl ether, 1,4:3,6-dianhydrosorbitol 2,5-diethyl ether (2,5-diethylisosorbide) and mixtures thereof. Preferred developers are gamma-valerolactone, cyrene, 2-methyl tetrahydrofuran, gamma-butyrolactone (GBL), cyclopentanone (CP), cyclohexanone, ethyl lactate (EL), n-butyl acetate (nBA) and dimethylsulfoxide (DMSO). These developers can be used individually or in combination of two or more to optimize the image quality for the composition and lithographic method.

In some embodiments, the dielectric film can be developed by using an aqueous developer. When the developer is an aqueous solution, it preferably contains one or more aqueous bases. Examples of suitable bases include, but are not limited to, inorganic alkalis (e.g., potassium hydroxide, sodium hydroxide), primary amines (e.g., ethylamine, n-propylamine), secondary amines (e.g., diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development by an organic developer, an optional rinse treatment can be carried out with an organic rinse solvent to remove residues. Suitable examples of organic rinse solvents include, but are not limited to, alcohols such as isopropyl alcohol, methyl isobutyl carbinol (MIBC), propylene glycol monomethyl ether (PGME), and amyl alcohol; esters such as n-butyl acetate (nBA), ethyl lactate (EL) and propylene glycol monomethyl ether acetate (PGMEA); ketnoes such as methyl ethyl ketone, and mixtures thereof.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or preferably, under a blanket of nitrogen and may be carried out by any suitable heating means.

In some embodiments, the patterned dielectric film includes at least one element having a feature size of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 micron). One important embodiment of this disclosure is that the dielectric films prepared from the dielectric film forming composition described herein can produce a patterned film with a feature size of at most about 3 microns (e.g., at most 2 microns or at most 1 micron) by a laser ablation method.

In some embodiments, the embodiment ratio (ratio of height to width) of a feature (e.g., the smallest feature) of the patterned dielectric film of this disclosure is at least about 1/3 (e.g., at least about 1/2, at least about 1/1, at least about 2/1, at least about 3/1, at least about 4/1, or at least about 5/1).

In some embodiments (e.g., when the dielectric film forming composition is non-photosensitive), the method to prepare a patterned dielectric film include converting the dielectric film into the patterned dielectric film by a laser ablation technique. Direct laser ablation method with an excimer laser beam is generally a dry, one step material removal to form openings (or patterns) in the dielectric film. In some embodiments, the wavelength of the laser is 640 nm or less (e.g., 157 nm, 193 nm, 248 nm, 308 nm, 351 nm, 405 nm, 445 nm, 470 nm, 520 nm, 528 nm, 555 nm, or 640 nm). Examples of suitable laser ablation methods include, but are not limited to, the methods described in U.S. Pat. Nos. 7,598,167, 6,667,551, and 6,114,240, the contents of which are hereby incorporated by reference.

In embodiments when the dielectric film forming composition is non-photosensitive, the composition can be used to form the bottom layer in a bilayer photoresist. In such embodiment, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a method for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. For example, the method can include the steps of: (a) depositing a dielectric film forming composition described herein on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a method to deposit a metal layer (e.g., an electrically conductive copper layer to create an embedded copper trace structure) on a semiconductor substrate. In some embodiment, to achieve this, a seed layer conformal to the patterned dielectric film is first deposited on the patterned dielectric film (e.g., outside the openings in the film). Seed layer can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-embodiment-ratio) features. The fill factor by sputtering deposition has been improved by collimating the sputtered flux. Typically, this is achieved by inserting between the target and substrate a collimator plate having an array of hexagonal cells.

Next step in the method is metal seeding deposition. A thin metal (e.g., an electrically conductive metal such as copper) seeding layer can be formed on top of the barrier layer in order to improve the deposition of the metal layer (e.g., a copper layer) formed in the succeeding step.

Next step in the method is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. U.S. Pat. Nos. 5,891,804, 6,399,486, and 7,303,992, the contents of which are hereby incorporated by reference.

In some embodiments, the method of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron, or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017/0175274, the contents of which are hereby incorporated by reference.

Some embodiments describe a method for surrounding a metal structured substrate containing conducting metal (e.g., copper) wire structures forming a network of lines and interconnects with the dielectric film described herein. The method includes
a) providing a substrate containing conducting metal wire structures that form a network of lines and interconnects on the substrate.
b) depositing a dielectric film forming composition described herein on the substrate to form a dielectric film (e.g., that surrounds the conducting metal lines and interconnects); and
c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method includes:
a) coating a carrier substrate (e.g., a substrate including at least one polymeric or plastic film) with a dielectric film forming composition described herein.
b) drying the coated dielectric film forming composition to form a dielectric layer (e.g., a photosensitive, dielectric layer); and
c) optionally, applying a protective layer to the dry film structure.

In some embodiments, the carrier substrate is a single or multiple layer polymeric or plastic film, which can include one or more polymers (e.g., polyethylene terephthalate). In some embodiments, the carrier substrate has excellent optical transparency, and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

Reliability is the probability that an electronic component will perform the required function under stressed conditions for a designated period. Preconditioning, Temperature Humidity Bias (THB), Biased Humidity Stress Test (bHAST), Unbiased HAST (uHAST), High Temp Storage (HTS) are commonly used stress test applied for semiconductor packaging materials. It is the proportion of devices used from time zero that will not have failed by a given time ‘t’.

The Highly Accelerated Stress Test (HAST) combines high temperature, high humidity, high pressure, and time to measure component reliability with or without electrical bias. In a controlled environment, HAST testing accelerates the stresses of the more traditional tests. It essentially functions as a corrosion failure test. Corrosion type failures are accelerated, uncovering flaws such as in packaging seals, materials, and joints over a shorter period of time.

Biased Highly Accelerated Stress Tests (bHAST) utilize the same variables (high pressure, high temperature and time) as HAST Tests, but add a voltage bias. The goal of BHAST testing is to accelerate corrosion within the device, thereby speeding up the test period. In unbiased HAST tests, humidity accelerates failure mechanisms related the presence of moisture for non-hermetic packages. Biased voltage under high humidity causes galvanic and electrochemical corrosion in non-hermitic packages in biased Humidity Stress Test (bHAST). For advanced/emerging package technologies, board level reliability (BLR) testing is conducted to determine the solder joint interconnect reliability using daisy-chained test vehicles. Failure analysis is conducted on failed samples to determine the cause.

As an accelerated version of the traditional non-condensing THB (temperature humidity bias) test, the HAST test has the advantage of adding high pressure and higher temperatures (up to 149° C.) to accelerate temperature and moisture induced failures in roughly one-tenth the time of THB. HAST and BHAST testing is usually run at 130° C./85% RH, but the conditions can also vary.

Typical HAST test conditions consist of 110 or 130° C. temperature, and 85% RH humidity and a test run time of 96 hours or 200 hours. Once the highly accelerated stress test is completed, tested samples are analyzed by microscope and SEM for changes happen during HAST conditions. HAST testing generally follows JEDEC spec JESD22 A110, “Highly Accelerated Temperature and Humidity Stress Test (HAST).” Biased Humidity Stress Test (bHAST) is the most sensitive stress test for reliability of a microelectronic device by using an organic dielectric film composition. Examples of bHAST methods used in evaluation of semiconductor devices have been described in, e.g., U.S. Pat. No. 9,874,813 and US patent application 2021/0272898 and the contents of which are hereby incorporated by reference.

TEG (Test Element Group) wafer with Cu post (pillar) plating was used for evaluation of wafer for such as material development, package stability under HAST conditions by inspection method. Examples of TEG wafers used in evaluation of semiconductor devices have been described in, e.g., U.S. Pat. Nos. 8,237,450 and 9,082,708, the contents of which are hereby incorporated by reference.

In some embodiments, the dielectric film of the dry film structure can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film forming composition described above except for the solvent.

In some embodiments, the dielectric loss tangent or dissipation factor of the dielectric film prepared from dielectric film forming composition described herein measured at 10 GHZ, 15 GHZ, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0.008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked dielectric film. In some embodiments, the carrier substrate can be removed before exposing the dielectric film to a source of radiation or heat.

Some embodiments of this disclosure describe a method of generating a planarizing dielectric film on a substrate with copper pattern. In some embodiments, the method includes depositing a dielectric film forming composition onto a substrate with copper pattern to form a dielectric film. In some embodiments, the method includes steps of:
a. providing a dielectric film forming composition of this disclosure, and
b. depositing the dielectric film forming composition onto a substrate with copper pattern to form a dielectric film, wherein the difference in the highest and lowest points on a surface of the dielectric film is at most about 2 microns (e.g., at most about 1.5 microns, at most about 1 micron, or at most about 0.5 micron).

In some embodiments, this disclosure features an article (or a three-dimensional object) containing at least one patterned dielectric film formed by a method described herein. Examples of such articles include a semiconductor substrate, a flexible film for electronics, a wire isolation, a wire coating, a wire enamel, and an inked substrate. In some embodiments, this disclosure features semiconductor devices that include one or more of these articles. Examples of semiconductor devices that can be made from such articles include an integrated circuit, a light emitting diode, a solar cell, and a transistor.

The contents of all publications cited herein (e.g., patents, patent application publications, and articles) are hereby incorporated by reference in their entirety.

The present disclosure is illustrated in more detail with reference to the following examples, which are for illustrative purposes and should not be construed as limiting the scope of the present disclosure.

### Synthesis Example 1: Preparation of Fully Imidized Polyimide (PI-I)

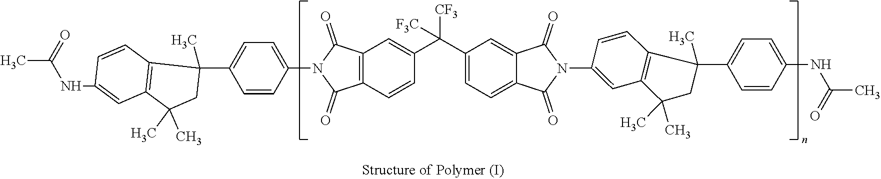

Solid 4,4′-(hexafluoroisopropylidene)bis(phthalic anhydride) (6FDA) (2.370 kg, 5.33 mole) was charged to a solution of 1-(4-aminophenyl)-1,3,3-trimethylindan-5-amine (also known as 4,4′-[1,4-phenylene-bis(1-methylethylidene)]bisaniline (DAPI)) (1.465 kg, 5.51 mole) in NMP (9.86 kg) at 25° C. The reaction mixture temperature was increased to 40° C. and allowed to react for 6 hours. Next, acetic anhydride (1.125 kg) and pyridine (0.219 kg) were added, and the reaction mixture temperature was increased to 100° C. and allowed to react for 12 hours.

The reaction mixture above was cooled to room temperature and transferred to a larger vessel equipped with a mechanical stirrer. The reaction solution was diluted with ethyl acetate and washed with water for one hour. After the stirring was stopped, the mixture was allowed to stand undisturbed. Once phase separation had occurred, the aqueous phase was removed. The organic phase was diluted with a combination of ethyl acetate and acetone and washed twice with water. The amounts of organic solvents (ethyl acetate and acetone) and water used in all of the washes are shown in Table 1.

TABLE 1

| | Wash 1 | Wash 2 | Wash 3 |
|---|---|---|---|
| Ethyl Acetate (kg) | 20.5 | 4.1 | 4.1 |
| Acetone (kg) | — | 2.3 | 2.3 |
| Water (kg) | 22.0 | 26.0 | 26.0 |

Cyclopentanone (10 kg) was added to the washed organic phase and the solution was concentrated by vacuum distillation to give a polymer solution containing polyimide (I) (PI-I). The solid % of final polymer was 29.19% and the weight average molecular weight (Mw) measured by GPC was 54,000 Daltons.

### Synthesis Example 2: Preparation of Fully Imidized Polyimide (PI-II)

The following is an example of preparation of a polyimide (PI) polymer using one diamine and one dianhydride wherein the isolation solvent (i.e., a lactone) was different from the purification solvents (i.e., a ketone and an ester).

Solid 4,4′-oxidiphthalic anhydride (ODPA, 664.5 g) was charged to a solution of 4,4′-diamino-2,2′-bis(trifluoromethyl) biphenyl (TFMB, 722.1 g) in NMP (3296 g) at 25° C. Additional NMP (1346 g) was used to rinse the dianhydride into the solution. The reaction temperature was increased to 40° C. and the mixture was allowed to react for 3 hours. Next, acetic anhydride (507.2 g) and pyridine (98.3 g) were added, the reaction temperature was increased to 100° C., and the mixture was allowed to react for 12 hours.

The reaction mixture was cooled to room temperature and a portion (899 g) was transferred to a 5-L vessel equipped with a mechanical stirrer. The reaction solution was diluted using a combination of cyclopentanone and n-butyl acetate and washed with water for one hour. Stirring was stopped and the mixture was allowed to stand undisturbed. Once phase separation had occurred, the aqueous phase was removed. The organic phase was diluted using cyclopentanone and washed three more times with water. The amounts of purification solvents (i.e., cyclopentanone and n-butyl acetate) and water used in all the washes are shown in Table 2.

TABLE 2

| | Wash 1 | Wash 2 | Wash 3 | Wash 4 |
|---|---|---|---|---|
| Cyclopentanone (g) | 1385 | 202 | — | — |
| n-Butyl Acetate (g) | 892 | — | — | — |
| Water (g) | 1329 | 1628 | 1631 | 1630 |

The washed organic phase was concentrated by vacuum distillation. Gamma-butyrolactone (605 g) was added as an isolation solvent and vacuum distillation was continued. The final polymer solution contained polyimide (II) (PI-II) at a concentration of 24.99 wt % and the weight average molecular weight (Mw) measured by GPC was 45,000 Daltons.

### Synthesis Example 3: Preparation of Fully Imidized Polyimide (PI-III)

A mixture of solid ODPA (94.78 g) and 6FDA (45.25 g) was charged to a solution of TFMB (135.5 g) in NMP (819 g) at 25° C. Additional NMP (100 g) was used to rinse the dianhydride into the solution. The reaction temperature was increased to 40° C. and the mixture was allowed to react for 3 hours. Next, acetic anhydride (94.25 g) and pyridine (18.27 g) were added, the reaction temperature was increased to 100° C., and the mixture was allowed to react for 12 hours.

The processing method was followed as Example 2 and the polyimide (III) (PI-III) thus formed was isolated in cyclopentanone and the weight average molecular weight (Mw) measured by GPC was 47,000 Daltons.

### Synthesis Example 4: Preparation of Fully Imidized Polyimide (PI-IV)

Solid ODPA (170.24 g) was charged to a solution of DAPI (74.59 g) and 2,2-Bis[4-(4-aminophenoxy)phenyl] propane (BAPP) (114.94 g) in NMP (979 g) at 25° C. Additional NMP (100 g) was used to rinse the dianhydride into the solution. The reaction temperature was increased to 40° C. and the mixture was allowed to react for 3 hours. Next, acetic anhydride (125.6 g) and pyridine (24.4 g) were added, the reaction temperature was increased to 100° C., and the mixture was allowed to react for 12 hours.

The processing method was followed by Example 2 and the polyimide (IV) (PI-IV) thus formed was isolated in GBL (30.60% solid) and the weight average molecular weight (Mw) measured by GPC was 42,000 Daltons.

### Synthesis Example 5: Preparation of Fully Imidized Polyimide (PI-V)

Solid ODPA (203.7 g) was charged to a solution of DAPI (133.2 g) and BAPP (68.4 g) in NMP (1115 g) at 25° C. Additional NMP (100 g) was used to rinse the dianhydride into the solution. The reaction temperature was increased to 40° C. and the mixture was allowed to react for 3 hours. Next, acetic anhydride (150 g) and pyridine (9 g) were added, the reaction temperature was increased to 100° C., and the mixture was allowed to react for 12 hours.

The processing method was followed by Example 2 and the polyimide (IV) (PI-V) thus formed was isolated in cyclopentanone (30.26% solid) and and the weight average molecular weight (Mw) measured by GPC was 43,000 Daltons.

### Synthesis Example 6: Preparation of Fully Imidized Polyimide (PI-VI)

Solid 2,2′,3,3′-benzophenone tetracarboxylic dianhydride (BTDA) (127.3 g) was charged to a solution of DAPI (106.55 g) in NMP (445 g) at 25° C. Additional NMP (100 g) was used to rinse the dianhydride into the solution. The reaction temperature was increased to 40° C. and the mixture was allowed to react for 3 hours. To perform the end-capping reaction, 2.97 grams of 4-methacryloxyethyl trimellitic anhydride) (META) and 2.0 grams of pyridine were charged to flask. The mixture was agitated at 60 degrees centigrade for 3 hours.

Next, acetic anhydride (60.4 g) and pyridine (23.43 g) were added, the reaction temperature was increased to 100° C., and the mixture was allowed to react for 12 hours. The processing method was followed by Example 2 and the polyimide (VI) (PI-VI) thus formed was isolated in cyclopentanone (30.26% solid) and and the weight average molecular weight (Mw) measured by GPC was 20,400 Daltons.

### Synthesis Example 7: Preparation of Fully Imidized Polyimide (PI-VII)

Solid 6FDA (61.08 g) was charged to a solution of DAPI (39.95 g) in NMP (500 g) at 25° C. Additional NMP (100 g) was used to rinse the dianhydride into the solution. The reaction temperature was increased to 40° C. and the mixture was allowed to react for 3 hours. To perform the endcapping reaction, 4.2 grams of exo-3,6-epoxy-1,2,3,6-tetrahydrophthalic anhydride (OxoNadic Anhydride) and 2.0 grams of pyridine were charged to flask. The mixture was agitated at 60 degrees centigrade for 3 hours.

Next, acetic anhydride (10.2 g) and pyridine (2.0 g) were added, the reaction temperature was increased to 100° C., and the mixture was allowed to react for 12 hours.

The processing method was followed by Example 2 and the polyimide (VII) (PI-VII) thus formed was isolated in cyclopentanone (30.5% solid) and the weight average molecular weight (Mw) measured by GPC was 13,200 Daltons.

### Synthesis Example 7: Preparation of Fully Imidized Polyimide (PI-VIII)

PI-VIII was a 31.7% solution of a polyimide polymer of ODPA, 6FDA and TFMB; and prepared in large scale having a weight average molecular weight of 44,786 Daltons in cyclopentanone as example PI-III

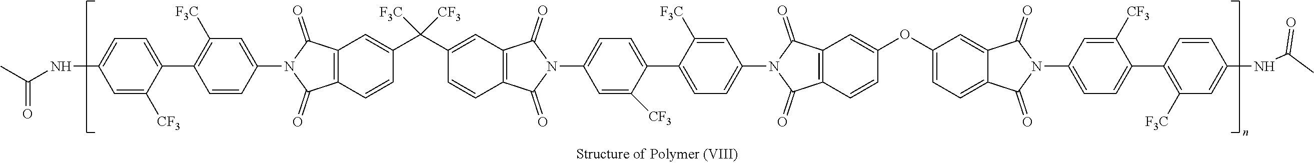

### Synthesis Example 9: Preparation of Fully Imidized Polyimide (PI-IX)

Solid ODPA (132.90 g) was charged to a solution of TFMB (128.09 g) and 3,5-diamino benzoic acid (6.09 g) in NMP (793 g) at 25° C. Additional NMP (100 g) was used to rinse the dianhydride into the solution. The reaction temperature was increased to 40° C. and the mixture was allowed to react for 3 hours. Next, acetic anhydride (98.74 g) and pyridine (19.2 g) were added, the reaction temperature was increased to 100° C., and the mixture was allowed to react for 12 hours.

The solution was diluted with 300 g of tetrahydrofuran (THF). Then, the solution was precipitated into 8 L of distilled water. After filtration, the wet cake was dried in air. The crude polymer was dissolved in 500 g of THF and precipitated into 8 L of distilled water. After filtration, the wet cake was dried in air and then under vacuum at 60° C. for 12 h for complete removal of moisture. The weight average molecular weight (Mw) measured by GPC was 50,000 Daltons.

### Synthesis Example 10: Preparation of Fully Imidized Polyimide (PI-X)

Solid ODPA (118.83 g) was charged to a solution of DAPI (128.09 g) and 3,5-diamino benzoic acid (5.92 g) in NMP (544 g) at 25° C. Additional NMP (100 g) was used to rinse the dianhydride into the solution. The reaction temperature was increased to 40° C. and the mixture was allowed to react for 3 hours. Next, acetic anhydride (87.3 g) and pyridine (16.9 g) were added, the reaction temperature was increased to 100° C., and the mixture was allowed to react for 12 hours.

The polymer was processed as example PI-IX. The weight average molecular weight (Mw) measured by GPC was 30,000 Daltons.

### Synthesis Example 11: Preparation of Fully Imidized Polyimide (PI-XI)

PI-XI is 32.2% solution of a polyimide polymer of 6FDA, DAPI and BAPP prepared in large scale having a weight average molecular weight was 54,000 Daltons in cyclopentanone.

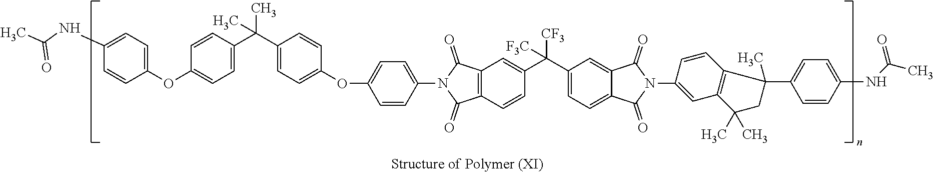

### Synthesis Example 12: Preparation of Fully Imidized Polyimide (PI-XII)

PI-XII is 33.65% solution of a polyimide polymer of 6FDA, DAPI and BAPP prepared in large scale of a having a weight average molecular weight of 74,000 Daltons in cyclopentanone

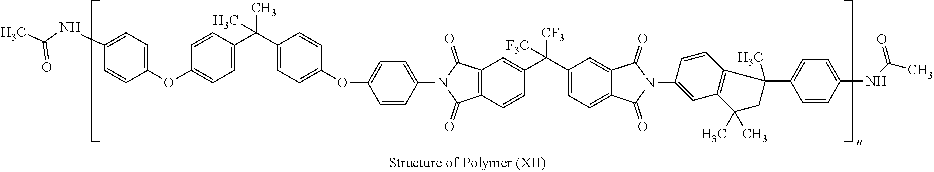

### Synthesis Example 13: Preparation of Fully Imidized Polyimide (PI-XIII)

PI-XIII is a blend of 49% PI-XI and 51% PI-XII.

### Synthesis Example 14: Preparation of Fully Imidized Polyimide (PI-XIV)

Solid ODPA (123.46 g) was charged to a solution of DAPI (79.91 g) and 4,4′-methylenebis(2,6-diethylaniline) (31.05 g) in NMP (603 g) at 25° C. Additional NMP (100 g) was used to rinse the dianhydride into the solution. The reaction temperature was increased to 40° C. and the mixture was allowed to react for 3 hours. Next, acetic anhydride (122.1) and pyridine (23.7 g) were added, the reaction temperature was increased to 100° C., and the mixture was allowed to react for 12 hours.

The polymer was processed as example PI-IX. The weight average molecular weight (Mw) measured by GPC was 41,000 Daltons.

### Abbreviations Described in Table 4 Further Below are as Follows:

(A) Resin component
Resins (Fully imidized polyimide) synthesized in Synthesis Examples 1 to 13 (PI I-XIII)

### (B) Multifunctional (Meth)Acrylate Crosslinker

B-1: tetra(ethylene glycol) diacrylate, DO48 (trade name, available from Green Chemical, Korea)
B-2: penta erythritol triacrylate, SR295 (trade name, available from Sartomer)
B-3: hexanediol diacrylate SR238 (trade name, available from Sartomer)
B-4: tricyclodecane dimethanol diacrylate SR833S (trade name, available from Sartomer)
B-5:1,6-bisphenol A (EO) 2 diacrylate (manufactured by Sigma Aldrich Corp.)
B-6:2-(tricyclo[5.2.1.02,6]dec-3-en-8-yloxy)ethyl acrylate (manufactured by Sigma Aldrich Corp.)
B-7: tris(2-hydroxy ethyl) isocyanurate triacrylate (manufactured by Tokyo Chemical Industry Co., Ltd.)
B-8:1,9-Nonanediol diacrylate (manufactured by Tokyo Chemical Industry Co., Ltd.)
B-9:1,10-decyldiol diacrylate SR595 (trade name, available from Sartomer)

### (C) Photo-Radical Polymerization Initiator

C-1: NCI-831 (trade name, available from ADEKA corporation),
C-2: IRGACURE OXE 01 (manufactured by BASF)
C3: IRGACURE OXE 02 (manufactured by BASF)
C4: KEYCURE VIS-831 (Titanium (4+) 2,4-cyclopentadienide 1-(2,4-difluorophenyl)-1H-pyrrol-3-ide (1:2:2) (manufactured by KING BROTHER CHEM CO., LTD)

### (D) Adhesion Promoter

D-1: gamma-glycidoxypropyltrimethoxysilane (Available from Gelest Corporation)
D-2: Gamma-Glycidoxypropyltrimethoxysilane or SilQuest A-187 (Available from Gelest Corporation)

### (E) Polymerization Inhibitor

E-1: monomethyl ether hydroquinone (manufactured by Tokyo Chemical Industry Co., Ltd.)
E-2: Parabenzoquinone (manufactured by Tokyo Chemical Industry Co., Ltd.) E-3: t-Butylcatechol (manufactured by Tokyo Chemical Industry Co., Ltd.)

### (F) Copper Corrosion Inhibitor

F-1:5-methyl benzotriazole (manufactured by Tokyo Chemical Industry Co., Ltd.) F-2:2-hydroxy-5-acrylyloxyphenyl-2H-benzotriazole (manufactured by Tokyo Chemical Industry Co., Ltd.)
F-3: 1H Tetrazole (manufactured by Tokyo Chemical Industry Co., Ltd.)
F-4:5-Phenyl 1H Tetrazole (manufactured by Tokyo Chemical Industry Co., Ltd.)
F-5: Ethyl 1H-tetrazole-5-acetate (manufactured by Tokyo Chemical Industry Co., Ltd.)
F-6: Ethyl 1H-tetrazole-5-carboxylate (manufactured by Tokyo Chemical Industry Co., Ltd.)
F-7:3-Amino-1,2,4-triazole (manufactured by Tokyo Chemical Industry Co., Ltd.)
F-8: -3,5-Diamino-1,2,4-triazole (manufactured by Tokyo Chemical Industry Co., Ltd.)

### (G) Surfactant

G-1: PolyFox 6320 (available from OMNOVA Solutions) in GBL
G-2:0.5 wt % solution of PolyFox 6320 (available from OMNOVA Solutions) in propylene carbonate,

### (H) Solvent

H-1: gamma-Butyrolactone (manufactured by Eastman)
H-2: Cyclopentanone (manufactured by Solvay)
H-3: Propylene Carbonate (manufactured by Huntsman)
H-4: Dimethyl sulfoxide (manufactured by Sigma Aldrich Corp.)
H-5: N-methyl-2-pyrrolidone (manufactured by Ashland

### (I) Additive

1-1: 50% solution of XU 378 in cyclopentanone (manufactured by Huntsman)
1-2: 50% solution of 2,2-bis(4-cyanatophenyl) propane in cyclopentanone (manufactured by Tokyo Chemical Industry Co., Ltd.)

### Photosensitive Composition Example 1

A photosensitive composition (FE-1) was prepared by using 80 g of polymer solution (PI-I), 14.69 g of GBL (H-1), 1.42 g of a 0.5 wt % solution of PolyFox 6320 (available from OMNOVA Solutions) in GBL (G-1), 0.71 g of gamma-glycidoxypropyltrimethoxysilane (D-1), 0.71 g of NCI-831E (trade name, available from ADEKA corporation), (C-1), 0.05 g of para-benzoquinone (E-2), 8.00 g of tetra(ethylene glycol) diacrylate (B-1), and 2.67 g of penta erythritol triacrylate (B-2). After being stirred mechanically for 24 hours, the solution was filtered by using a 0.2 microns filter.

### Photosensitive Composition Example 2

A photosensitive composition (FE-2) was prepared by using 100 parts of a 32.46 percent solution of a polyimide polymer (PI-XI), 93.2 parts of H-2, 27.5 parts of H-1,5.9 parts of G-1, 5 parts of D-1,3.0 part of C-2, 0.1 parts of E-3 32.5 parts of B-1, 12.5 parts of B-2, 5.0 parts of B-6 and 0.62 parts of F-1. After being stirred mechanically for 24 hours, the solution was filtered by using a 0.2 microns filter (Ultradyne from Meissner Corporation, cat #CLTM0.2-552).

### Photosensitive Composition Example 3

A photosensitive composition (FE-3) was prepared by using 100 parts of a 29.19% solution of a polyimide polymer (PI-XI) having a weight average molecular weight of 54,000 Daltons in cyclopentanone, 9.5 parts of H-2, 142 parts of H-3, 6.0 parts of G-2, 5.0 parts of D-1, 3.0 parts of C-2, 0.2 parts of hydroquinone E-1, 37.5 parts of B-1 12.5 parts of B-2, 10.0 parts of 1-2 and 0.5 parts of F-1 After being stirred mechanically for 24 hours, the solution was filtered by using a 0.2 micron filter (Ultradyne from Meissner Corporation, cat #CLTM0.2-552).

### Composition Examples FE-4 to FE-35

The photosensitive polyimide film-forming compositions were prepared based on 100 parts of polymer. After being mixed thoroughly as example FE-1, the solutions were filtered by using a 0.2 microns filter (Ultradyne from Meissner Corporation, cat #CLTM0.2-552.

### Composition Examples FE-41 to FE-42

The photosensitive polyimide film-forming compositions are prepared based on 100 parts of polymer. After being mixed thoroughly as example FE-1, the solutions are filtered by using a 0.2 microns filter (Ultradyne from Meissner Corporation, cat #CLTM0.2-552.

Table 4 provides the compositions for formulations FE-4 to FE-35 and FE-41 to FE-42.

### Dry Film Example 1

A photosensitive dielectric film forming composition was prepared by using 1345.24 g of a 31.69% solution of a polyimide polymer (I) (PI-I) having a weight average molecular weight of 54000 in cyclopentanone (H-2), 1021.91 g of propylene carbonate (H-3) 102.31 g of a 0.5 wt % solution of PolyFox 6320 in cyclopentanone (G-1), 21.31 g of methacryloxypropyltrimethoxy silane (D-1), 34.11 g of a 50% solution of XU-378 (Bisphenol M Cyanate ester available from Huntsman) (1-1) in cyclopentanone, 12.79 g of 2-(O-benzoyloxime)-1-[4-(phenylthio)phenyl]-1,2-octanedione (Irgacure OXE-1 available from BASF (C-2), 0.43 g of monomethyl ether hydroquinone (E-1), 138.55 g of tetraethylene glycol diacrylate (B-1), 53.39 g of pentaerythritol triacrylate (B-2), 26 g of dicumyl peroxide, and 0.426 g of 5-methyl benzotriazole (F-1). After being stirred mechanically for 24 hours, the solution was filtered by using a 0.2-micron filter (Ultradyne from Meissner Corporation, cat #CLTM0.2-552).

This photosensitive dielectric film forming composition obtained above was applied using a slot die coater with a line speed of about 2 feet/minute (61 cm per minute) with 60 microns clearance onto a polyethylene terephthalate (PET) film (TCH21, manufactured by DuPont Teijin Films USA) having a width of 16.2″ and thickness of 36 microns (which was used as a carrier substrate), and dried at 194° F. to obtain a photosensitive polymeric layer. On this polymeric layer, a biaxially oriented polypropylene film having a width of 16″ and a thickness of 30 microns (BOPP, manufactured by Impex Global, Houston, TX) was laid over by a roll compression to act as a protective layer. The carrier substrate, the photosensitive polymeric layer, and the protective layer together form a dry film (i.e., DF-1).

### Lithographic Method Example 1

The photosensitive composition FE-1 was spin coated on a silicon wafer and baked at 95° C. for 6 minutes using a hot plate to form a coating with a thickness of 7.95 microns. The photosensitive polyimide film was exposed at various levels of exposure energy using a Cannon 4000 IE i-line stepper.

Unexposed portions were removed by using cyclopentanone as a developer (1×40 seconds of dynamic development), followed by rinsing the developed film with PGMEA for 15 seconds to form a pattern. A resolution of 4 microns at a photospeed of 100 mJ/cm² was achieved. The film thickness loss was 17.9%.

### General Procedure for Mechanical Properties Measurement of Film

A filtered polymer solution was applied via spin coating onto a silicon oxide wafer to obtain a film with a thickness of approximately 12.0 microns to 15.0 microns. The coating was dried on a hot plate oven at 90° C. for 10 minutes The film was then exposed to 500 mJ/cm². Finally, the film was baked at 230° C. for 3 hours under vacuum using YES oven. The film was delaminated from silicon oxide layer by using 2% hydrofluoric acid solution and dried in air at 50° C. for 2 hours. After cooling to room temperature, the film was characterized by DMA for Tg measurement.

### Three-Dimensional Object Example 1

The photosensitive dielectric film forming composition described in Dry Film Example 1 is converted to films deposited on various substrates used in microelectronics and packaging applications. A film is deposited on a 100 mm silicon wafer by spin coating about 5 g of the solution at a spin speed of about 2000 rpm. The film is dried at a temperature of 105° C. for 3 minutes on a hotplate to obtain 12-micron clear and transparent film is obtained. Film quality in terms of transparency, defect count, and uniformity is expected to meet the requirements for semiconductor packaging applications.

The above procedures are repeated on aluminum, copper, and silicon nitride wafers. All films thus obtained are expected to meet the requirements for semiconductor packaging applications.

### Reliability Test Examples

The dielectric film forming composition of Example FE 21-35 were spin-coated at 1200 rpm onto a TEG chip with copper-plated line/space pattern ranging from 2/2 microns, 8/8 microns, 15/15 microns at 6-12 microns thickness and baked at 95 degrees centigrade for 5 minutes using a hot plate to form a coating with a thickness of about 13 microns. The dielectric film forming compositions were then blanket exposed at 500 mJ/cm² by using an LED i-line exposure tool. The compositions were cured at 170-230 degrees centigrade for 3 hours in a YES oven.

Reliability tests were then performed as explained below and summarized in Table 3.

Unbiased Highly Accelerated Stress Test (uHAST) (JESD22-A118)
The purpose of uHSAT simulates extreme operating conditions. (Similar to Autoclave).
Description: Devices are baked in a chamber at an extreme temperature and humidity for various lengths of time. The devices are then ATE evaluated for electrical failures.
Variables: Temp=130° C./Humidity=85% RH/Time=96 or 210 hoursTEG chips were heated in an ESPEC reliability test chamber at 130 degrees centigrade, 85 percent RH for unbiased Humidity Stress Test (uHAST) for 96, 168 and 210 hours. The cracking or delamination was checked by optical microscope at 96, 168, and 210 hours, or by cross-sectional SEM after cleaving and ion milling samples at 96, 168, and 210 hours.
Biased Highly Accelerated Stress Test (bHAST) (JESD22-A110)
The purpose of bHAST test simulates extreme operating conditions (Very similar to uHAST).
Description: Devices are baked in a chamber at an extreme temperature and humidity for various lengths of time. The devices are subjected to bias while the devices are in the chamber. The devices are then electrically tested using ATE for electrical failures. Variables: Temp=130° C./Humidity=85% RH/Time=96 or 264 hours, 5-20 volts voltage bias levels.

TEG chips were heated in an ESPEC reliability test chamber at 130 degrees centigrade, 85 percent RH for biased Humidity Stress Test (bHAST) for 96 hours under 5-20 volts. The cracking or delamination was checked by optical microscope at 96 hours, or by cross-sectional SEM after cleaving and ion milling samples at 96 hours. High Temperature Operating Life (HTS)

The operating life failure rate period generally continues for a considerably longer time. HTS is used to determine device resistance to prolonged operating stress, including both electrical and thermal mechanism. HTS is normally a reliability measure for the design/layout of the device in a given fab method.

The purpose of the test simulates the operating lifetime under a specified set of conditions.

Variables: Temp=175° C./Time=1000 hours.

The cracking or delamination was checked by optical microscope at 100, 500,1000 hours, or by cross-sectional SEM after cleaving and ion milling samples at 100, 500, 1000 hours.

### Thermal Cycle (TCT) (JESD22-A104/IPC-9701)

The purpose of the TCT test accelerates the effects of thermal expansion mismatch between the component solder joint and the system board.

Description: A thermal cycle is defined by the temperature extremes, dwell/soak time at the extremes and the temperature ramp rate. The resistance of all daisy chain nets is measured either in-situ or following pre-defined read points and compared to the initial resistance.
Variables: Temp=150° C. (top) and −40° C. (bottom)/Time˜60 minutes per cycle, number of cycles=1000.
The cracking or delamination was checked by optical microscope at 100, 500, 1000 cycles, or by cross-sectional SEM after cleaving and ion milling samples at 100,500, 1000 cycles.
Biased Humidity Stress Test (bHAST) is the most sensitive stress test for reliability of a microelectronic device by using an organic dielectric film composition.

TABLE 3
Summary of Reliability Test

| Formulation | | | | |
|---|---|---|---|---|
| Example(type) | HAST | bHAST | HTS | TCT |
| FE-1 (21000M) | pass | Not measured | pass | Pass |
| FE-5 (LTC | pass | fail | pass | Pass |
| 23000) | | | | |
| FE-9 (25000) | pass | fail | pass | Pass |
| FE-30 (FD- | pass | pass | pass | Pass |
| 7000) | | | | |
| FE-33 | pass | pass | pass | pass |
| (25000X08H) | | | | |

### Conditions:

HAST: 130° C./85% RH/96 hours,
bHAST: 5-15 volts, 130° C./85% RH/96 hours,
HTS: 175° C./1000 hours,
TCT: −40° ° C. to 150° C./1000 cycles.

TABLE 4
Formulation FE-4-FE42

| Formu- | | | | | | | Cu | Cu | | | | |
|---|---|---|---|---|---|---|---|---|---|---|---|---|
| lation | PI | SSC 1 | SSC 2 | Initiator | AP | Additive | Inhibitor 1 | Inhibitor 2 | Inhibitor | | Solvent 1 | Solvent 2 |
| FE-4 | PI-XIII | B-3(35) | B-2(10) | C-2(3) | D1(5) | I-1 (5) | F-4(2.2) | F-2(1) | E-3(0.1) | | H-2 (70%) | H-3 (30%) |
| | (100) | | | | | | | | | | | |
| FE-5 | PI-XIII | B-1(37.5) | B-2 | C-1 | D-1(5) | | F-1(0.5) | | E-3(0.1) | | H-2 (45%) | H-3 (55%) |
| | (100) | | (12.5) | (1.2) | | | | | | | | |
| | | | | C-3 | | | | | | | | |
| | | | | (1.8) | | | | | | | | |
| FE-6 | PI-VIII | B-3(45) | | C-1(3) | D-1(5) | I-1 (5) | F-4(2.2) | F-2(1) | E-3(0.1) | | H-2 (70%) | H-3 (30%) |
| | (100) | | | | | | | | | | | |
| FE-7 | PI-VIII | B-3(45) | | C-2(3) | D-1(5) | I-1 (5) | F-4(2.2) | F-2(1) | E-3(0.1) | | H-2 (70%) | H-3 (30%) |
| | (100) | | | | | | | | | | | |
| FE-8 | PI-VIII | B-3(45) | B-2(10) | C-2(3) | D-1(5) | I-1 (5) | F-4(2.2) | F-2(1) | E-3(0.1) | | H-2 (70%) | H-3 (30%) |
| | (100) | | | | | | | | | | | |
| FE-9 | PI-VIII | B-1(35) | B-2(10) | C-2(4) | D-1(5) | I-1 (5) | F-4(2.2) | F-2(1) | E-3(0.1) | | H-2 (70%) | H-3 (30%) |
| | (100) | | | | | | | | | | | |
| FE-10 | PI-VIII | B-1(45) | | C-2(3) | D-1(5) | I-1 (5) | F-8(0.5) | F-2(1) | E-3(0.1) | | H-2 (70%) | H-3 (30%) |
| | (100) | | | | | | | | | | | |
| Formu- | | | | | | | Cu | Cu | | | | |
| lation | PI | SSC 1 | SSC 2 | Initiator | AP | Additive | Inhibitor 1 | Inhibitor 2 | Inhibitor | Solvent 1 | Solvent 2 | Surfactant |
| FE-11 | PI-XIII | B-1 | B-2(5) | C-2(3) | D-1(5) | I-1 (5) | F-1(0.5) | F-2(1) | E-3(0.1) | H-2 | H-3 | |
| | (100) | (35) | | | | | | | | (70%) | (30%) | |
| FE-12 | PI-XIII | B-1 | B-2(5) | C-2(3) | D-1(5) | I-1 (5) | F-3(0.5) | F-2(1) | E-3(0.1) | H-2 | H-3 | |
| | (100) | (35) | | | | | | | | (70%) | (30%) | |
| FE-13 | PI-XIII | B-1 | B-2(5) | C-2(3) | D-1(5) | I-1 (5) | F-4(0.5) | F-2(1) | E-3(0.1) | H-2 | H-3 | |
| | (100) | (35) | | | | | | | | (70%) | (30%) | |
| FE-14 | PI-XIII | B-1 | B-2(5) | C-2(3) | D-1(5) | I-1 (5) | F-5(0.5) | F-2(1) | E-3(0.1) | H-2 | H-3 | |
| | (100) | (35) | | | | | | | | (70%) | (30%) | |
| FE-15 | PI-XIII | B-1 | B-2(5) | C-2(3) | D-1(5) | I-1 (5) | F-6(0.5) | F-2(1) | E-3(0.1) | H-2 | H-3 | |
| | (100) | (35) | | | | | | | | (70%) | (30%) | |
| FE-16 | PI-XIII | B-1 | B-2(5) | C-2(3) | D-1(5) | I-1 (5) | F-7(0.5) | F-2(1) | E-3(0.1) | H-2 | H-3 | |
| | (100) | (35) | | | | | | | | (70%) | (30%) | |
| FE-17 | PI-XIII | B-1 | B-2(5) | C-2(3) | D-1(5) | I-1 (5) | F-8(0.5) | F-2(1) | E-3(0.1) | H-2 | H-3 | |
| | (100) | (35) | | | | | | | | (70%) | (30%) | |
| FE-18 | PI-XIII | B-1 | B-2(5) | C-2(3) | D-1(5) | I-1 (5) | F-4(1.0) | F-2(1) | E-3(0.1) | H-2 | H-3 | |
| | (100) | (35) | | | | | | | | (70%) | (30%) | |
| FE-19 | PI-XIII | B-1 | B-2(5) | C-2(3) | D-1(5) | I-1 (5) | F-4(1.5) | F-2(1) | E-3(0.1) | H-2 | H-3 | |
| | (100) | (35) | | | | | | | | (70%) | (30%) | |
| FE-20 | PI-XIII | B-1 | B-2(5) | C-2(3) | D-1(5) | I-1 (5) | F-4(2.2) | F-2(1) | E-3(0.1) | H-2 | H-3 | G-1 (0.05) |
| | (100) | (35) | | | | | | | | (70%) | (30%) | |

| Formu- | | | | | | | Cu | | | | |
|---|---|---|---|---|---|---|---|---|---|---|---|
| lation | PI | SSC 1 | SSC 2 | Initiator | AP | Additive | Inhibitor 1 | Inhibitor | Solvent 1 | Solvent 2 | |
| FE-21 | PI-IV | B-1(45) | | C-2(3) | D-1(5) | I-1 (5) | F-4(2.2) | E-3(0.1) | H-1 (70%) | H-2(30%) | |
| | (100) | | | | | | | | | | |
| FE-22 | PI-IV | B-3(45) | | C-2(3) | D-1(5) | I-1 (5) | F-4(2.2) | E-3(0.1) | H-1 (70%) | H-2(30%) | |
| | (100) | | | | | | | | | | |
| FE-23 | PI-IV | B-4(35) | | C-2(3) | D-1(5) | I-1 (5) | F-4(2.2)) | E-3(0.1) | H-1 (70%) | H-2(30%) | |
| | (100) | | | | | | | | | | |
| FE-24 | PI-IV | B-3(45) | B-6(5) | C-2(3) | D-1(5) | I-1 (5) | F-4(2.2) | E-3(0.1) | H-1 (70%) | H-2(30%) | |
| | (100) | | | | | | | | | | |
| FE-25 | PI-IV | B-3(50) | | C-2(3) | D-1(5) | I-1 (5) | F-4(2.2) | E-3(0.1) | H-1 (70%) | H-2(30%) | |
| | (100) | | | | | | | | | | |
| FE-26 | PI-V | B-3(55) | | C-2(3) | D-1(5) | I-1 (5) | F-4(2.2) | E-3(0.1) | H-1 (70%) | H-2(30%) | |
| | (100) | | | | | | | | | | |
| FE-27 | PI-V | B-3(50) | B-6(5) | C-2(3) | D-1(5) | I-1 (5) | F-4(2.2) | E-3(0.1) | H-1 (70%) | H-2(30%) | |
| | (100) | | | | | | | | | | |
| FE-28 | PI-IV | B-3(45) | B-7((5) | C-2(3) | D-1(5) | I-1 (5) | F-4(2.2) | E-3(0.1) | H-1 (70%) | H-2(30%) | |
| | (100) | | | | | | | | | | |
| FE-29 | PI-IV | B-5(45) | | C-2(3) | D-1(5) | I-1 (5) | F-4(2.2) | E-3(0.1) | H-1 (70%) | H-2(30%) | |
| | (100) | | | | | | | | | | |
| FE-30 | PI-IV | B-5(45) | B-2(5) | C-2(3) | D-1(5) | | F-1(0.5) | E-3(0.1) | H-1 (70%) | H-2(30%) | |
| | (100) | | | | | | | | | | |
| FE-31 | PI-VIII | B-3 | B-2(5) | C-2(3) | D-1(5) | I-1 (5) | F-1(0.5) | E-3(0.1) | H-1 (70%) | H-2(30%) | |
| | (100) | (22.5), | | | | | | | | | |
| | | B-8 | | | | | | | | | |
| | | (22.5) | | | | | | | | | |
| FE-32 | PI-VIII | B-3 | B-2(10) | C-2(3) | D-1(5) | I-1 (5) | F-1(0.5) | E-3(0.1) | H-1 (70%) | H-2(30%) | |
| | (100) | (22.5), | | | | | | | | | |
| | | B-8 | | | | | | | | | |
| | | (22.5) | | | | | | | | | |
| FE-33 | PI-VIII | B-3(20), | B-2(5) | C-2(3) | D-1(5) | I-1 (5) | F-1(0.5) | E-3(0.1) | H-1 (70%) | H-2(30%) | |
| | (100) | B-8(20) | | | | | | | | | |
| FE-34 | PI-VIII | B-3 | B-2(5) | C-2(3) | D-1(5), | I-1 (5) | F-1(0.5) | E-3(0.1) | H-1 (70%) | H-2(30%) | |
| | (100) | (22.5), | | C-4(2) | | | | | | | |
| | | B-9 | | | | | | | | | |
| | | (22.5) | | | | | | | | | |
| FE-35 | PI-VIII | B-5(45) | B-2(5) | C-2(3) | D-1(3) | | F-1(0.5) | E-3(0.1) | H-1 | | |
| | (100) | | | | | | | | (100%) | | |
| FE-36 | PI-XIV | B-9(45) | B-2(10) | C-2(5) | D-1(5) | | F-1(0.5) | E-3(0.1) | H-1 (100%) | | |
| | (100) | | | | | | | | | | |
| FE-37 | PI-XIV | B-3 | B-2(10) | C-2(5) | D-1(5) | | F-1(0.5) | E-3(0.1) | H-1 (100%) | | |
| | (100) | (22.5), | | | | | | | | | |
| | | B-9(22.5) | | | | | | | | | |
| FE-38 | PI-XIV | B-3(45) | B-2(10) | C-2(5) | D-1(5) | | F-1(0.5) | E-3(0.1) | H-1 (100%) | | |
| | (100) | | | | | | | | | | |
| FE-41 | PI-IX | B-3(35) | B-2(10) | C-2(3) | D-2(5) | I-1 (5) | F-4(2.2) | F-2(1) | E-3(0.1) | H-2 (70%) | H-3 (30%) |
| | (100) | | | | | | | | | | |
| FE-42 | PI-X | B-3(35) | B-2(10) | C-2(3) | D-2(5) | I-1 (5) | F-4(2.2) | F-2(1) | E-3(0.1) | H-2 (70%) | H-3 (30%) |
| | (100) | | | | | | | | | | |

What is claimed is:

1. A method, comprising:
providing a composition comprising a hydrophobic multifunctional (meth)acrylate crosslinker and a polymer; and
processing the composition to provide a dielectric layer,
wherein, when the dielectric layer is present in a microelectronic device, the microelectronic device exhibits good reliability.

2. The method of claim 1, wherein the hydrophobic multifunctional (meth)acrylate crosslinker has a log P value of at least 0.5.

3. The method of claim 1, wherein the hydrophobic multifunctional (meth)acrylate crosslinker comprises at least one member selected from the group consisting of at least one difunctional, trifunctional, tetrafunctional, and hexafunctional (meth)acrylates, and wherein each of the hydrophobic multifunctional (meth)acrylate crosslinkers has a log P value from about 0.5 to about 8.0.

4. The method of claim 1, wherein the composition further comprises a corrosion inhibitor.

5. The method of claim 4, wherein the corrosion inhibitor has a log P value from about −1.0 to about 6.0.

6. The method of claim 1, wherein the composition further comprises a photoinitiator.

7. The method claim 6, wherein the photoinitiator comprises at least one member selected from the group consisting of oxime ester, titanocene, acyl germanium compound, and peroxide.

8. The method of claim 1, wherein the composition further comprises an organic solvent.

9. The method of claim 8, wherein the organic solvent comprises at least one member selected from the group consisting of alkylene carbonates, lactones, cycloketones, linear ketones, alkyl esters, alkyl ester alcohol, alkyl ether alcohols, alkyl ether ester, glycol ester, glycol ether, cyclic ether, pyrrolidone, and dialkylsulfoxide.

10. The method of claim 1, wherein the polymer comprises at least one member selected from the group consisting of a polybenzoxazole precursor polymer, a polyimide precursor polymer, or a fully imidized polyimide polymer.

11. The method of claim 1, wherein the polymer comprises a fully imidized polyimide polymer.

12. The method of claim 11, wherein the fully imidized polyimide polymer comprises a functional group.

13. The method of claim 11, wherein the fully imidized polyimide polymer comprises an alkaline soluble polymer.

14. The method of claim 11, wherein the fully imidized polyimide polymer comprises a fluorine-atom free polymer.

15. The method of claim 1, wherein the polymer is present in an amount of from about 0.1% to about 55% by weight based on a solid weight of the composition.

16. The method of claim 1, wherein the hydrophobic multifunctional (meth)acrylate crosslinker is present in an amount of from about 0.5% to about 25% by weight based on a solid weight of the composition.

17. The method of claim 1, wherein the composition further comprises at least one member selected from the group consisting of an adhesion promoter, a surfactant, a filler, a pigment, a dye, and a metal-containing (meth)acrylate compound.

18. The method of claim 1, wherein the composition further comprises at least one photosensitizer selected from the group consisting of benzophenones, thioxanthones, anthraquinones, anthracenes, and coumarines.

19. The method of claim 1, wherein the composition is substantially free of fluorine.

20. The method of claim 1, wherein, when the dielectric layer is present in the microelectronic device, the microelectronic device passes at least one test selected from the group consisting of HAST, bHAST, HTS and TCT.

21. The method of claim 1, further comprising:
depositing the composition on a substrate to form a film;
exposing the film to radiation or heat or a combination of radiation and heat to crosslink the hydrophobic multifunctional (meth)acrylate crosslinker to provide the dielectric layer; and
patterning the dielectric layer to form a patterned dielectric layer having openings.

22. A patterned dielectric layer produced by the method of claim 21.

23. The method of claim 1, further comprising:
incorporating the dielectric layer into the microelectronic device.

24. The method of claim 21, wherein the substrate comprises at least one member selected from the group consisting of an organic film, an epoxy molded compound (EMC), silicon, glass, copper, stainless steel, a copper cladded laminate (CCL), aluminum, silicon oxide, and silicon nitride.

25. The method of claim 21, further comprising:
optionally depositing a seed layer on the patterned dielectric film; and
depositing a metal layer in an opening in the patterned dielectric film to form a metal pattern.

26. The method of claim 1, wherein the semiconductor device is an integrated circuit, a light emitting diode, a solar cell, or a transistor.

27. The method of claim 1, further comprising:
supporting the dielectric film with a carrier layer.

28. The method of claim 1, further comprising:
coating a carrier substrate with the composition to form a coated composition;
drying the coated composition to form the dielectric layer; and
optionally applying a protective layer to the dielectric layer to form the dry film structure.

29. The method of claim 28, further comprising:
applying the dry film structure onto an electronic substrate to form a laminate, wherein the dielectric layer in the laminate is disposed between the electronic substrate and the carrier substrate.

30. The method of claim 1, further comprising:
depositing the dielectric film onto a substrate having a copper pattern to form a dielectric film, wherein the difference in height between the highest and lowest points on a surface of the dielectric film is at most about 2 microns.

31. A composition, comprising:
a fully imidized polyimide; and
a hydrophobic multifunctional (meth)acrylate crosslinker,
wherein the dielectric composition is suitable to provide a dielectric layer that imparts good reliability to a microelectronic device when the dielectric layer is present in the microelectronic device.

32. The composition of claim 31, wherein the hydrophobic multifunctional (meth)acrylate crosslinker has a log P value of at least 0.5.

33. The composition of claim 31, wherein the hydrophobic multifunctional (meth)acrylate crosslinker comprises at least one member selected from the group consisting of at least one difunctional, trifunctional, tetrafunctional, and hexafunctional (meth)acrylates, and wherein each of the hydrophobic multifunctional (meth)acrylate crosslinkers has a log P value from about 0.5 to about 8.0.

34. The composition of claim 31, further comprising a corrosion inhibitor.

35. The composition of claim 34, wherein the corrosion inhibitor has a log P value from about −1.0 to about 6.0.

36. The composition of claim 31, further comprising a photoinitiator.

37. The composition of claim 36, wherein the photoinitiator comprises at least one member selected from the group consisting of oxime ester, titanocene, acyl germanium compound, and peroxide.

38. The composition of claim 31, further comprising an organic solvent.

39. The composition of claim 38, wherein the organic solvent comprises at least one member selected from the group consisting of alkylene carbonates, lactones, cycloketones, linear ketones, alkyl esters, alkyl ester alcohol, alkyl ether alcohols, alkyl ether ester, glycol ester, glycol ether, cyclic ether, pyrrolidone, and dialkylsulfoxide.

40. The composition of claim 31, wherein the polymer comprises at least one member selected from the group consisting of a polybenzoxazole precursor polymer, a polyimide precursor polymer, or a fully imidized polyimide polymer.

41. The composition of claim 31, wherein the polymer comprises a fully imidized polyimide polymer.

42. The composition of claim 41, wherein the fully imidized polyimide polymer comprises a functional group.

43. The composition of claim 41, wherein the fully imidized polyimide polymer comprises an alkaline soluble polymer.

44. The composition of claim 41, wherein the fully imidized polyimide polymer comprises a fluorine-atom free polymer.

45. The composition of claim 31, wherein the polymer is present in an amount of from about 0.1% to about 55% by weight based on a solid weight of the composition.

46. The composition of claim 31, wherein the hydrophobic multifunctional (meth)acrylate crosslinker is present in an amount of from about 0.5% to about 25% by weight based on a solid weight of the composition.

47. The composition of claim 31, further comprising at least one member selected from the group consisting of an adhesion promoter, a surfactant, a filler, a pigment, a dye, and a metal-containing (meth)acrylate compound.

48. The composition of claim 31, further comprising at least one photosensitizer selected from the group consisting of benzophenones, thioxanthones, anthraquinones, anthracenes, and coumarines.

49. The composition of claim 31, wherein the composition is substantially free of fluorine.

50. The composition of claim 31, wherein, when the dielectric layer is present in the microelectronic device, the microelectronic device passes at least one test selected from the group consisting of HAST, bHAST, HTS and TCT.
